(19) United States
(12) Patent Application Publication
(10) Pub. No.: US 2007/0082477 A1
(43) Pub. Date: Apr. 12, 2007

(54) Integrated circuit fabricating techniques employing sacrificial liners

(75) Inventors: Mehul Naik, San Jose, CA (US); Srinivas Gandikota, Santa Clara, CA (US); Girish Dixit, San Jose, CA (US); Dennis Yost, Los Gatos, CA (US)

Correspondence Address: PATENT COUNSEL;APPLIED MATERIALS, INC., Legal Affairs Department, P.O.BOX 450A, Santa Clara, CA, 95052, US

(73) Assignee: Applied Materials, Inc.

(21) Appl. No.: 11/245,712

(22) Filed: Oct. 6, 2005

(51) Int. Cl. H01L 21/4763; H01L 29/76; H01L 29/94; H01L 31/00

(52) U.S. Cl. 438/622; 257/408

(57) ABSTRACT

The present invention provides techniques for fabricating integrated circuit structures in semiconductor wafer fabrication. A via hole is prepared in a dielectric stack having a bottom via etch stop layer. The via hole is not extended through the via etch stop layer at this stage of the process. The via hole is partly filled with a sacrificial via fill such that a recess without sacrificial via fill is formed in the top portion of the via hole. A substantially conformal sacrificial layer is deposited on the top surface of the dielectric stack and in the recess. Then, a photoresist layer is deposited on the sacrificial fill. A trench etch mask overlaying the via hole, is developed in the photoresist layer. This mask is etched through the sacrificial layer that is formed on the top surface of the dielectric stack as well as through the sacrificial fill and sacrificial layer that is present in the via hole. Additionally, the mask is employed for etching a trench partly through the dielectric layer thereby forming a trench and an underlying via hole. The via hole is then extended through the via etch stop layer. Subsequently, the photoresist layer and the sacrificial layer are removed from the top surface of the dielectric stack resulting in a trench and underlying via hole that is suitable for fabricating a dual damascene structure. Alternatively, a recess can be formed by depositing a substantially conformal sacrificial layer on the top surface of the dielectric stack and in the via hole to form a lined via hole. The lined via hole is then partly filled with a sacrificial via fill such that a recess without sacrificial via fill is formed in the top portion of the lined via hole. Next, a photoresist layer is deposited in the recess and on the sacrificial liner that is deposited on the top surface of the dielectric stack.

### FIELD OF THE INVENTION

The present invention relates to integrated circuit fabricating techniques wherein sacrificial liners and sacrificial fills are employed to substantially reduce or prevent photoresist poisoning.

### BACKGROUND OF THE INVENTION

A semiconductor device such as an IC (integrated circuit) generally has electronic circuit elements such as transistors, diodes and resistors fabricated integrally on a single body of semiconductor material. The various circuit elements are connected through conductive connectors to form a complete circuit which can contain millions of individual circuit elements. Advances in semiconductor materials and processing techniques have resulted in reducing the overall size of the IC circuit elements while increasing their number on a single body. Additional miniaturization is highly desirable for improved IC performance and cost reduction. Interconnects provide the electrical connections between the various electronic elements of an IC and they form the connections between these elements and the device's external contact elements, such as pins, for connecting the IC to other circuits. Typically, interconnect lines form horizontal connections between electronic circuit elements while conductive vias form vertical connections between the electronic circuit elements, resulting in layered connections.

A variety of techniques are employed to create interconnect lines and vias. One of these techniques involves a process generally referred to as dual damascene, which includes forming a trench and an underlying via hole. The trench and the via hole are simultaneously filled with a conductor material, for example a metal, thus simultaneously forming an interconnect line and an underlying via. Examples of conventional dual damascene fabrication techniques are disclosed in Kaanta et al., “Dual Damascene: A ULSI Wiring Technology”, Jun. 11-12, 1991, VMIC Conference, IEEE, pages 144-152 and in U.S. Pat. No. 5,635,423 to Huang et al., 1997.

An example of a prior art dual damascene technique is shown in IC structures illustrated in FIGS. 1A-1E. As depicted in FIG. 1A, an IC structure 110 is fabricated by depositing a dielectric stack 112 on a semiconductor substrate 114. Dielectric stack 112 is fabricated by means of the sequential deposition of a conventional via etch stop layer 116, a conventional dielectric layer 118 and a conventional hard mask or ARC (antireflective coating) layer 120. A via hole 122 is formed through layers 120 and 118, utilizing a typical etch process wherein layer 116 forms the etch stop layer. Then, as illustrated in FIG. 1B showing IC structure 130, a conventional photoresist layer 132 is deposited on layer 120. Subsequently, a trench pattern 134 is formed in resist layer 132 such that trench pattern 134 is aligned with underlying via hole 122.

Resist layer 132 comprises a typical positive resist, i.e. a resist that becomes soluble in a suitable solvent as a result of exposure to radiation that is projected on the resist layer. Desirably, resist trench pattern 134 is fabricated such that it enables the etching of an interconnect line that meets the required replication of the IC chip circuit layout interconnect line. With reference to FIG. 1C, illustrating IC structure 140, a conventional anisotropic etch process is utilized to etch trench pattern 134 through layer 120. In a subsequent timed etch process, trench pattern 134 is etched partly through layer 118 to form a trench 142 having the desired depth. This step shortens the depth of via hole 122, shown in FIG. 1A, to a reduced depth illustrated in via hole 144, shown in FIG. 1C. Via hole 144 is extended through etch stop 116 by etching the via pattern through layer 116, such that via hole 144 exposes a region 146 of substrate 114. Resist layer 132 and hard mask or ARC layer 120 (FIG. 1C) are then removed, resulting in IC structure 150 illustrated in FIG. 1D.

The fabricating process is continued to form IC structure 160, illustrated in FIG. 1E. Via hole 144 and trench 142 are simultaneously filled with a conductive material such as a metal, e.g. copper or aluminum, to form dual damascene structure 162 comprising via 164 and interconnect line 166. It is noted that via 164 contacts region 146 of substrate 114, thereby forming an electrically conductive contact with an IC element in substrate 114 such as a gate (not shown) of a transistor (not shown), or alternatively forming a contact with an interconnect line (not shown) embedded in substrate 114.

With reference to FIGS. 1C and 1E it is noted that layer 120 can be retained (not shown) following the removal of resist layer 132. The resulting dual damascene structure (not shown) includes an interconnect line that is formed in a trench through layer 120 and partly through layer 118.

As stated in connection with resist trench pattern 134 shown in FIG 1B, it is desirable that this pattern results in etching an interconnect line meeting the design requirements. However, it is well known to persons of ordinary skill in the art that it is difficult to achieve this desirable result, since current and future IC fabricating methods and materials are likely to be affected by resist poisoning as will be described and illustrated in connection with IC structure 210 shown in FIG. 2. IC structure 210 is fabricated by depositing a dielectric stack 212 on a semiconductor substrate 214. Dielectric stack 214 includes etch stop layer 216, dielectric layer 118 and hard mask or ARC layer 220. A via hole 222 is fabricated in the dielectric stack. Dielectric stack 212, substrate 214 and via hole 222 shown in FIG. 2 are similar to features 114, 116 and 122 respectively shown in FIGS. 1A and 1B.

With reference to FIG. 2 a conventional positive photoresist layer 224 is deposited on layer 220. A trench pattern 225 is formed in the resist layer by exposure to radiation and subsequent removal of the exposed resist by solution in an appropriate solvent. However, as shown in FIG. 2, contaminated resist residue such as residues 226 and 228 can be formed as a result of resist poisoning. Typically, these residues are not soluble in resist solvents that are utilized to remove exposed resist. It is known that resist residues that are formed as a result of resist poisoning greatly interfere with anisotropically etching the underlying materials such as dielectric layer 218, thus resulting in difficulties or failure in meeting CD (critical design) parameters for etching a trench in a “via first” dual damascene fabricating procedure. A plug (not shown) of resist residue can form, thereby completely covering the underlying cavity. Resist poisoning is believed to be caused by gases that are formed due to etching of dielectric materials or due to outgassing from the underlying structure, such as gases outgassing from layers 216 and 218 in via hole 222. It is further known that gases containing nitrogen compounds are particularly prone to cause resist poisoning. However, this undesirable phenomenon is not limited to nitrogen compounds. Dielectric materials such as nitrides and CDO (carbon-doped silicon oxide) are known to contribute to resist poisoning.

It is known to form dual damascene structures wherein one or more of the dielectric layers include CDO materials, such as oxidized organo silane materials that are formed by partial oxidation of an organo silane compound, such that the dielectric material includes a carbon content of at least 1% by atomic weight, as described in U.S. Pat. Nos. 6,072,227 (Yau et al., 2000) and 6,054,379 (Yau et al., 2000) and U.S. patent application Ser. No.: 09/553,461 which was filed Apr. 19, 2000, a continuation-in-part of U.S. Pat. No.: 6,054,379. Commonly assigned U.S. Pat. Nos. 6,072,227 and 6,054,379, and U.S. patent application Ser. No. 09/553,461 are herein incorporated by reference in their entireties.

The oxidized organo silane materials, described in the '227 and '379 patents and the '461 patent application, are formed by incomplete or partial oxidation of organo silane compounds generally including the structure:

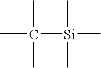

In this structure, —C— is included in an organo group and some C-Si bonds are not broken during oxidation. Preferably —C— is included in an alkyl, such as methyl or ethyl, or an aryl, such as phenyl. Suitable organo groups can also include alkenyl and cyclohexenyl groups and functional derivatives. Preferred organo silane compounds include the structure SiHₐ(CH₃)_{b}(C₂H₅)_{c}(C₆H5)_{d}, where a=1 to 3, b=0 to 3, c=0 to 3, and a+b+c+d=4, or the structure Si₂Hₑ,(CH₃)_{f}(C₂H₅)_{g}(C₆H₅)ₕ, where e=1 to 5, f=0 to 5, g=0 to 5, h=0 to 5, and e+f+g+h=6.

Suitable organo groups include alkyl, alkenyl, cyclohexenyl, and aryl groups and finctional derivatives. Examples of suitable organo silicon compounds include but are not limited to:

| | |
|---|---|
| methylsilane | CH₃—SiH₃ |
| dimethylsilane | (CH₃)₂—SiH₂ |
| trimethylsilane | (CH₃)₃—SiH |
| tetramethylsilane | (CH₃)₄—Si |
| dimethylsilanediol | (CH₃)₂—Si(OH)₂ |
| ethylsilane | CH₃—CH₂—SiH₃ |
| phenylsilane | C₆H₅—SiH₃ |
| diphenylsilane | C₆H₅)₂—SiH₂ |
| diphenylsilanediol | (C₆H₅)₂—Si—(OH)₂ |
| methylphenylsilane | C₆H₅—SiH₂—CH₃ |
| disilanomethane | SiH₃—CH₂—SiH₃ |
| bis(methylsilano)methane | CH₃—SiH₂—CH₂—SiH₂—CH₃ |
| 1,2-disilanoethane | SiH₃—CH₂—CH₂—SiH₃ |
| 1,2-bis(methylsilano)ethane | CH₃—SiH₂—CH₂—CH₂—SiH₂—CH₃ |
| 2,2-disilanopropane | SiH₃—C(CH₃)₂—SiH₃ |
| 1,3,5-trisilano-2,4,6-trimethylene | —(—SiH₂CH₂—)₃— (cyclic) |
| dimethyldimethoxysilane | (CH₃)₂—Si—(OCH₃)₂ |
| diethyldiethoxysilane | (CH₃CH₂)₂—Si—(OCH₂CH₃)₂ |
| dimethyldiethoxysilane | (CH₃)₂—Si—(OCH₂CH₃)₂ |
| diethyldimethoxysilane | (CH₃CH₂)₂—Si—(OCH₂CH₃)₂ |
| 1,3-dimethyldisiloxane | CH₃—SiH₂—O—SiH₂—CH₃ |
| 1,1,3,3-tetramethyldisiloxane | (CH₃)₂—SiH—O—SiH—(CH₃)₂ |
| hexamethyldisiloxane | (CH₃)₃—Si—O—Si—(CH₃)₃ |
| 1,3-bis(silanomethylene)disiloxane | (SiH₃—CH₂—SiH₂—)₂—O |
| bis(1-methyldisiloxanyl)methane | (SiH₃—SiH₂—O—SiH₂—)₂—CH₂ |
| 2,2-bis(1-methyldisiloxanyl)propane | (CH₃—SiH₂—O—SiH₂—)₂—O(CH₃)₂ |
| 2,4,6,8-tetramethylcyclotetrasiloxane | —(—SiHCH₃—O—)₄— (cyclic) |
| octamethylcyclotetrasiloxane | —(—Si(CH₃)₂—O—)₄— (cyclic |
| 2,4,6,8,10-pentamethylcyclopentasiloxane | —(—SiHCH₃—O—)₅— (cyclic) |
| 1,3,5,7-tetrasilano-2,6-dioxy-4,8-dimethylene | —(SiH₂—CH₂—SiH₂—O—)₂— (cyclic) |
| 2,4,6-trisilanetetrahydropyran | —SiH₂—CH₂—SiH₂—CH₂—SiH₂—O— (cyclic) |
| 2,5-disilanetetrahydrofuran | —SiH₂—CH₂—CH₂—SiH₂—O— (cyclic) |
| and fluorinated derivatives thereof. | |

Preferred organo silane compounds include but are not limited to: methylsilane; dimethylsilane; trimethylsilane; tetramethylsilane; dimethylsilanediol; diphenylsilane; diphenylsilanediol; methylphenylsilane; bis(methylsilano)methane; 1,2-bis(methylsilano)ethane; 1,3,5-trisilano-2,4,6-trimethylene; dimethyldimethoxysilane; diethyldiethoxysilane; dimethyldiethoxysilane; diethyldimethoxysilane; hexamethyldisiloxane; octamethylcyclotetrasiloxane; and fluorinated derivatives thereof. The most preferred organo silane compounds include methyl silane and trimethyl silane.

The organo silane compounds are oxidized during deposition by reaction with oxygen (O₂) or oxygen containing compounds such as nitrous oxide (N₂O) and hydrogen peroxide (H₂O₂), such that the carbon content of the deposited film is from 1% to 50% by atomic weight, preferably about 20%. The oxidized organo silane layer has a dielectric constant of about 3.0. Carbon, including some organo finctional groups, remaining in the oxidized organo layer contributes to low dielectric constants and good barrier properties providing a barrier that inhibits for example diffusion of moisture or metallic components. These oxidized organo silane materials exhibit good adhesion properties to silicon oxide and silicate glass as well as typical dielectric materials employed in IC structures. The above described oxidized organo silanes include BLACK DIAMOND™ technology, available from Applied Materials, Inc. located in Santa Clara, Calif.

Plasma conditions for depositing a layer of the oxidized organo silane material having a carbon content of at least 1% by atomic weight, include a high frequency RF power density from about at least 0.16 W/cm² and a sufficient amount of organo silane compound with respect to the oxidizing gas to provide a layer with carbon content of at least 1% by atomic weight. When oxidizing organo silane materials with N₂O, a preferred high frequency RF power density ranges from about 0.16 W/cm² to about 0.48 W/cm². These conditions are particularly suitable for oxidizing CH₃—SiH₃ with N₂O. Oxidation of organo silane materials such as (CH₃)₃—SiH with O₂ is preferably performed at a high frequency RF power density of at least 0.3 W/cm², preferably ranging from about 0.9 W/cm² to about 3.2 W/cm². Suitable reactors for depositing this material include parallel plate reactors such as those described in the '379 and '227 patents. As shown in the '227 and '379 patents and in the '461 application, the oxidized organo silane materials including at least 1% of carbon can be utilized in multi-layered structures such as are used, for example, in fabricating dual damascene integrated circuit structures.

The current and future need for etching dielectric cavities such as via holes and trenches for use in very compact integrated circuits requires reduced cavity diameters, increased aspect ratios and reduced spaces between etched features. These requirements have resulted in more severe resist poisoning difficulties. Also, there is a well recognized need for photoresist materials that are sensitive to radiation sources having a reduced wavelength compared with previously used resists. This need is driven by the requirement for improved resolution of the IC layout image that is projected on the resist. Resist materials that are sensitive to radiation having a wavelength >248 nm generally exhibit a relatively low sensitivity to resist poisoning. Reduced wavelengths such as 248 nm, particularly 193 and 157 nm are considerably more prone to forming an insoluble resist poison residue

It is known to reduce the resist poison phenomenon by filling a cavity such as via 222 (FIG. 2) with an organic fill (not shown), prior to depositing a positive resist and then forming the positive resist mask. However, this technique typically causes fence formation inside the trench. Also, U.S. Pat. No. 6,583,046 (the '046 patent) discloses techniques for the elimination or substantial reduction of resist poisoning that is caused by a nitrogen-containing atmospheres. The techniques disclosed in the '046 patent include treatment of exposed surfaces, such as low-k dielectric layers with hydrogen at an elevated temperature, prior to forming a resist on the structures. While the techniques disclosed in the '046 patent appear to have considerable merit, these techniques appear to be applicable mainly to nitrogen caused resist poisoning and are therefore not expected to address resist poisoning caused by non-nitrogen materials or compounds. Additionally, the '046 techniques may require relatively high treatment temperatures in order to be effective, and may thereby have a negative effect on the properties of the IC structure.

Accordingly, the need exists for improved IC fabricating techniques that eliminate or substantially reduce photoresist poisoning.

### SUMMARY OF THE INVENTION

In one embodiment of the invention a dielectric stack, including a via etch stop bottom layer, is fabricated on a semiconductor substrate. A via hole is etched in the dielectric stack, such that etching the via hole is stopped on the etch stop layer. Thereafter, a sacrificial fill is deposited in the via hole. Subsequently, a via hole recess is created by removing a top portion of the sacrificial fill. A substantially conformal sacrificial liner is then deposited on the top surface of the dielectric stack and in the recess. A photoresist layer having an interconnect line trench etch mask is formed on the sacrificial liner. An interconnect line trench is etched through the sacrificial liner that is deposited on the stack and partly through the stack such that the trench is aligned with the via hole. Trench etching includes removing sacrificial fill and sacrificial liner from the via hole. The via is then etched through the via etch stop layer, resulting in an integrated circuit structure including an interconnect line trench and via hole that is adapted for fabricating an electrically conductive dual damascene structure.

In another embodiment of the present invention a dielectric stack, including a via etch stop bottom layer is fabricated on a semiconductor substrate. A via hole is etched in the stack, such that etching the via hole is stopped on the etch stop layer. Thereafter, a sacrificial liner is deposited in the via hole and on the top surface of the stack, thereby forming a lined via hole. A sacrificial fill is deposited in the lined via hole. Subsequently, a via hole recess is created by removing a top portion of the sacrificial fill from the lined via hole, thus forming a lined recess. An interconnect line trench is etched through the sacrificial layer that is deposited on the stack and partly through the dielectric stack such that the trench is aligned with the via hole. Trench etching includes removing sacrificial fill and sacrificial liner from the via hole. The via is then etched through the via etch stop layer, resulting in an integrated circuit structure including an interconnect line trench and a via hole that is adapted for fabricating an electrically conductive dual damascene structure.

In a further embodiment of the present invention a dielectric stack, including a via etch stop bottom layer is deposited on a semiconductor substrate. A via hole is etched in the stack, such that etching the via hole is stopped on the etch stop layer. A substantially conformal sacrificial liner is deposited in the via hole and on the top surface of the stack, resulting in a lined via hole. A sacrificial via fill is deposited on the sacrificial liner that is formed inside the via and on the top surface of the stack. Subsequently, the sacrificial fill is removed from the sacrificial liner that is formed on the top surface of the stack. Also, the sacrificial fill is removed from a top portion of the lined via hole, thereby creating a via hole recess. Next, a photoresist layer is deposited in the recess and on the sacrificial liner that is deposited on the top surface of the stack. An interconnect line trench etching mask is developed in the photoresist layer. This mask is etched through the sacrificial liner that is formed on the top surface of the stack and also through the sacrificial fill that is deposited in the lined via hole, the sacrificial liner in the via hole and partly through the dielectric stack. The via hole is then extended through the via etch stop layer. Then, the photoresist layer is removed, followed by the removal of the sacrificial liner from the top surface of the stack. The structure thus fabricated includes an interconnect line trench overlaying a via hole wherein the trench and via hole are suitable for fabricating a Cu dual damascene structure therein.

### BRIEF DESCRIPTION OF THE DRAWINGS

FIGS. 1A-1E are schematic cross-sectional views illustrating the fabrication of a prior art structure at sequential stages.

FIG. 2 is a schematic cross-sectional view of a prior art structure.

FIGS. 3A-3I are schematic cross-sectional views illustrating an embodiment of IC structures of the present invention at sequential stages.

FIGS. 4A-4B are schematic cross-sectional views illustrating an embodiment of IC structures of the present invention at sequential stages.

FIGS. 5A-5C are schematic cross-sectional views illustrating an embodiment of IC structures of the present invention at sequential stages.

FIGS. 6A-6E are schematic cross-sectional views illustrating an embodiment of IC structures of the present invention at sequential stages.

FIG. 7 is a schematic cross-sectional view illustrating an IC structure fabricated in an embodiment of the present invention.

FIGS. 8A-8F are schematic cross-sectional views illustrating an embodiment of IC structures of the present invention at sequential stages.

FIG. 9 is a schematic cross-sectional view illustrating an IC structure fabricated in an embodiment of the present invention.

FIGS. 10-10I are schematic cross-sectional views illustrating an embodiment of IC structures of the present invention at sequential stages.

FIGS. 11A-11C are schematic cross-sectional views illustrating in an embodiment of the present invention at sequential stages.

FIGS. 12A-12F are schematic cross-sectional views illustrating an embodiment of IC structures of the present invention at sequential stages.

FIG. 13 is a schematic cross-sectional view illustrating an IC structure fabricated in an embodiment of the present invention.

FIGS. 14A-14F are schematic cross-sectional views illustrating an embodiment of IC structures of the present invention at sequential stages.

FIG. 15 is a schematic cross-sectional view illustrating an IC structure fabricated in an embodiment of the present invention.

FIGS. 16A-16C are schematic cross-sectional views illustrating an embodiment of IC structures of the present invention at sequential stages.

FIG. 17 is a schematic cross-sectional view illustrating an IC structure fabricated in an embodiment of the present invention.

FIG. 18 is a schematic cross-sectional view illustrating an IC structure fabricated in an embodiment of the present invention.

FIGS. 19A-19D are schematic cross-sectional views illustrating an embodiment of IC structures of the present invention at sequential stages.

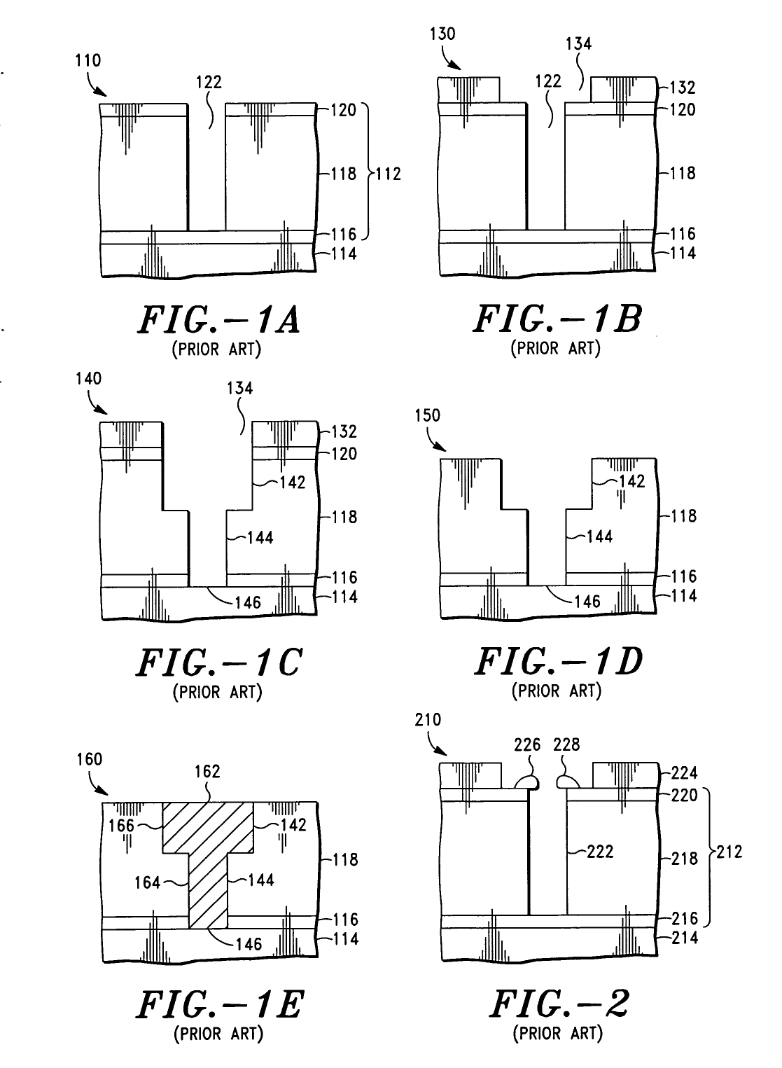

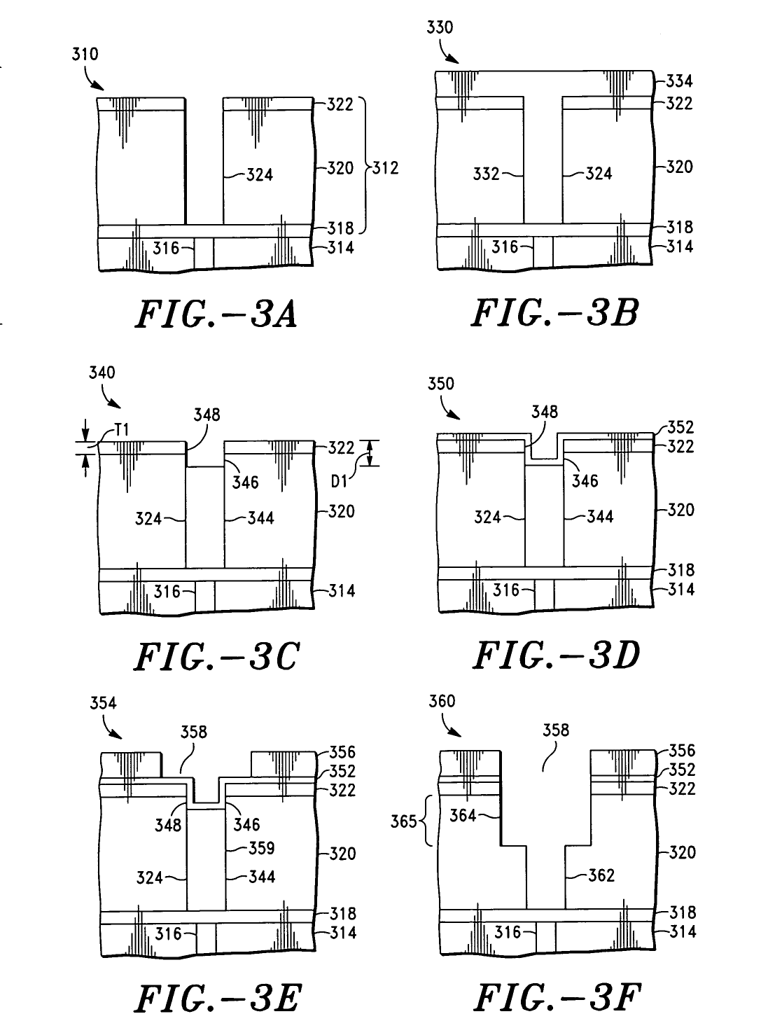

### DETAILED DESCRIPTION OF THE INVENTION

While describing the invention and its embodiments, certain technology will be utilized for the sake of clarity. It is intended that such terminology includes the recited embodiments as well as all equivalents.

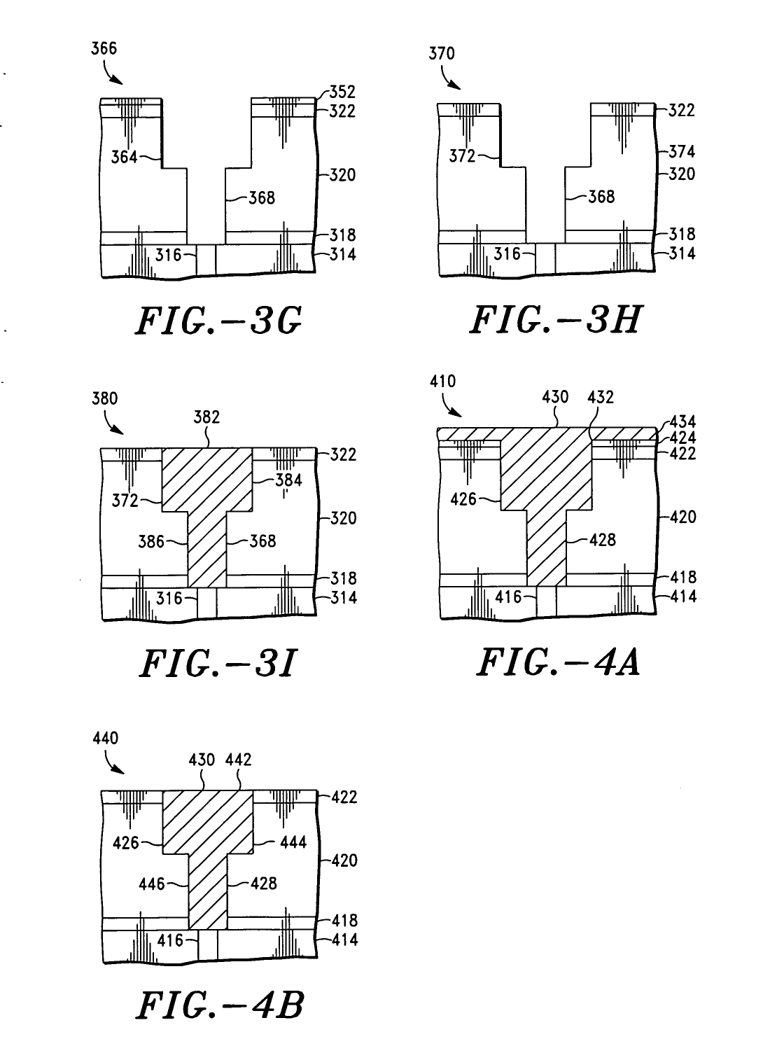

One embodiment, schematically illustrated in FIGS. 3A-31, shows a novel processing sequence, using a sacrificial fill and a sacrificial liner, for forming IC structures including IC structures having one or more dual damascene structures. The expression “integrated circuit structure” as defined herein, means completely formed integrated circuits and partially formed integrated circuits.

FIG. 3A shows an IC structure 310 including a dielectric stack 312 that is deposited on a substrate, such as a semiconductor substrate 314. The expression “semiconductor substrate” as defined herein, means structures and devices comprising typical IC elements, components, interconnects and semiconductor materials. Electrically conductive element 316, positioned in substrate 314, provides an electrically conductive contact with one or more IC elements (not shown) of the substrate. Typical examples of electrically conductive elements include interconnects, vias and transistor gate contacts. Dielectric stack 312 is fabricated by means of a sequential deposition of a conventional via etch stop layer 318, a conventional first dielectric layer 320 and a second dielectric layer 322 preferably comprising a conventional ARC (antireflective coating) layer or a conventional hard mask layer or a conventional dual hard mask layer, having a thickness T1. Employing conventional anisotropic etching methods and materials, a via hole 324 is etched through layers 322 and 320. The via hole etch process is stopped on etch stop layer 318.

As depicted in FIG. 3B showing IC structure 330, via hole 324 is filled with a sacrificial via fill 332 comprising organic or inorganic fill material that is deposited by conventional means such as spin-on, CVD (chemical vapor deposition) or in an etch chamber. Typically, the sacrificial via fill results in an overburden 334 on layer 322. Referring to FIG. 3C showing an IC structure 340, a conventional etch technique such as etch back is employed to remove any overburden 334 of the sacrificial fill from layer 322, and to remove a top portion of the sacrificial via fill, thereby reducing the height of the via fill to form a sacrificial via fill 344 and creating an unfilled via hole top portion or recess 346 having a side wall 348. Typically, depth D1 of recess 346 exceeds thickness T1 of layer 322, see FIG. 3C.

Novel IC structure 350 depicted in FIG. 3D is fabricated according to techniques of the present invention wherein a substantially conformal sacrificial liner 352 is deposited on layer 322 and on sacrificial via fill 344 such that side wall 348 is coated with the sacrificial liner. The terms “substantial” and “substantially” as used herein mean at least 90% of the relevant 100% value. As illustrated in FIG. 3E, IC structure 354 is formed by depositing a conventional photoresist layer 356 on sacrificial liner 352 including sacrificial liner 352 that is formed in recess 346. Resist layer 356 is then patterned and developed to form trench etch mask 358. Employing conventional anisotropic etching procedures and materials, the etch pattern of mask 358 is etched through layers 352 and 322. This etch procedure is also utilized to remove sacrificial liner 352 and via fill 344 from upper section 359 (FIG. 3E) of via 324 wherein the trench will be fabricated, see FIG. 3F. Subsequently, a conventional anisotropic timed etch is employed to partly etch the trench etch pattern through first dielectric layer 320 as illustrated in FIG. 3F showing IC structure 360. The trench etch process can be utilized to simultaneously remove sacrificial fill 344 from the via hole. Alternatively, sacrificial fill 344 can be removed from the via hole in a separate process after etching the trench. This etching procedure results in via hole 362 positioned in layer 320, such that via hole 362 comprises the lower portion of via hole 324 (FIG. 3A). Also, a trench 364 is formed in layers 352 and 322 and in upper portion 365 of layer 320 (FIG. 3F) by means of this trench etching procedure. As shown in IC structure 366 illustrated in FIG. 3G, resist layer 356 is stripped. In a separate conventional anisotropic etch procedure, via hole 362 is extended through via etch stop layer 318 thereby forming via hole 368 that exposes conductive element 316.

Sacrificial layer 352 can be removed from layer 322 in a subsequent processing step, using such techniques as are known for removal of the material that is used in layer 352. However, it is also contemplated to remove liner 352 from layer 322 during the etching process for etching the trench. The resulting IC structure 370, shown in FIG. 3H, depicts via hole 368 as well as trench 372 that is formed in second dielectric layer 322 and in upper portion 374 of first dielectric layer 320. Finally, using dual damascene methods and materials such as are known to a person of ordinary skill in the art, conductive material for example a metal such as copper or aluminum is deposited simultaneously in via hole 368 and in trench 372. The simultaneous deposition of conductive material in via hole 368 and trench 372 results in an IC structure 380, illustrated in FIG. 3I, having a dual damascene structure 382 that includes an interconnect line 384 formed in trench 372, and a via 386 fabricated in via hole 368. Interconnect line 384 can be defined using well known techniques such as conventional CMP (chemical mechanical polishing) and etch back. Via 386 contacts conductive element 316 of substrate 314, see FIG. 3I.

It is noted that the materials comprising sacrificial via fill 332 (FIG. 3B) can be substantially the same as the materials comprising sacrificial liner 352 (FIG. 3D). Also, the materials comprising sacrificial via fill 332 can be different from those comprising the sacrificial liner.

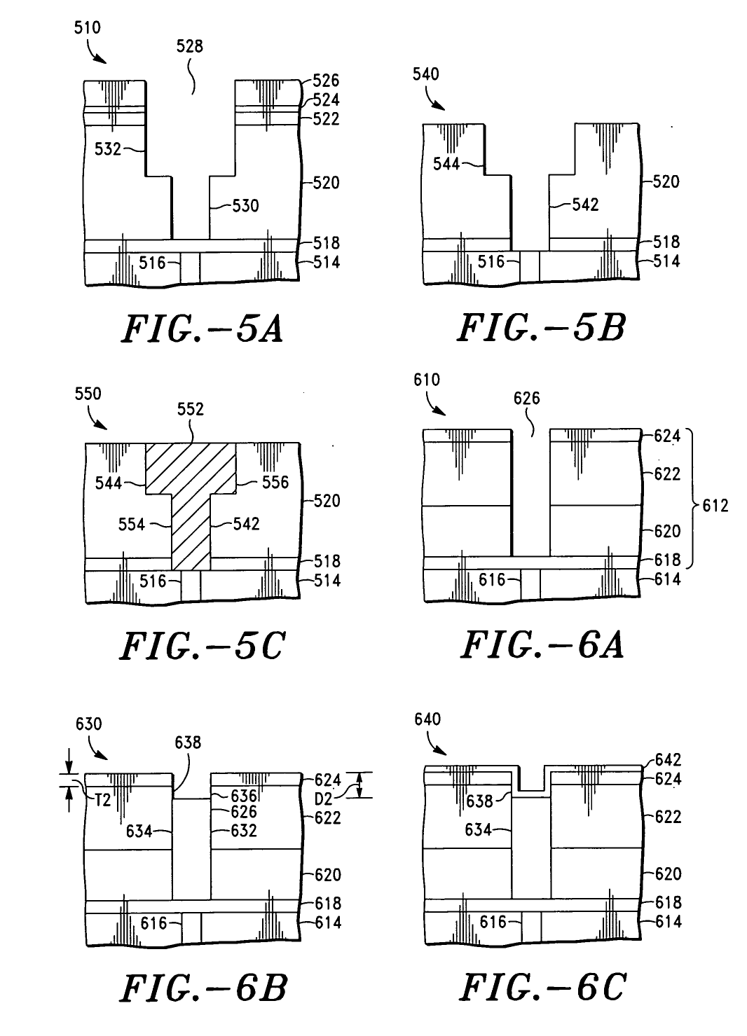

FIGS. 4A and 4B illustrate a novel alternative dual damascene fabrication procedure for the method of the present invention described and illustrated in connection with FIGS. 3H and 3I. In this alternative procedure a novel dual damascene technique is employed, as illustrated in FIG. 4A showing an IC structure 410, to simultaneously deposit a conductive material 430, for example a metal such as copper or aluminum in the via and trench cavities of structure 366 shown in FIG. 3G. Features 414, 416, 418, 420, 422, 424, 426 and 428 shown in FIG. 4A are similar to features 314, 316, 318, 320, 322, 352, 364 and 368 respectively depicted in FIG. 3G.

Returning to FIG. 4A, conductive material 430 deposited in via hole 428 and trench 426, is simultaneously deposited in trench pattern 432 that is formed in sacrificial layer 424. Additionally, an overburden 434 of conductive material 430 may be formed on layer 424. Conventional CMP is then employed to remove layer 424 and conductive material 430 that is deposited inside trench pattern 432 of layer 424. Any overburden 434 of material 430 that can be formed on layer 424 is also removed by this CMP procedure, resulting in IC structure 440 shown in FIG. 4B. IC structure 440 includes a dual damascene structure 442 having an interconnect line 444 and a via 446, wherein the interconnect line and the via are formed simultaneously. It is noted that structures 440 (FIG. 4B) and 380 (FIG. 31) are similar in structure and in materials comprising these structures.

FIGS. 5A-5C illustrate an additional dual damascene fabrication method of the present invention. FIG. 5A depicts an IC structure 510 that is similar to IC structure 360, shown in FIG. 3F. It is noted that features 514, 516, 518, 520, 522, 524, 526, 528, 530 and 532 shown in FIG. 5A are similar to features 314, 316, 318, 320, 322, 352, 356, 358, 362 and 364 respectively depicted in FIG. 3F.

Returning to FIG. 5A, layers 522, 524 and 526 are removed using such techniques as are known to a person of ordinary skill in the art for the removal of materials comprising these layers. Additionally, via 530 is extended by anisotropically etching the via pattern through via etch stop layer 518. Removal of layers 522, 524 and 526, and etching the via pattern through via etch stop layer 518 results in IC structure 540, see FIG. 5B, showing an extended via hole 542 and an interconnect line trench 544. Thereafter, a conventional dual damascene technique is employed for simultaneously filling via hole 542 and trench 544 with a conductive material, for example a metal such as copper or aluminum, to fabricate IC structure 550, depicted in FIG. 5C. As a result of the simultaneous filling of via hole 542 and trench 544 a dual damascene structure 552 is formed. Dual damascene structure 552 includes a via 554 and an interconnect line 556. Via 554 contacts conductive element 516 of substrate 514.

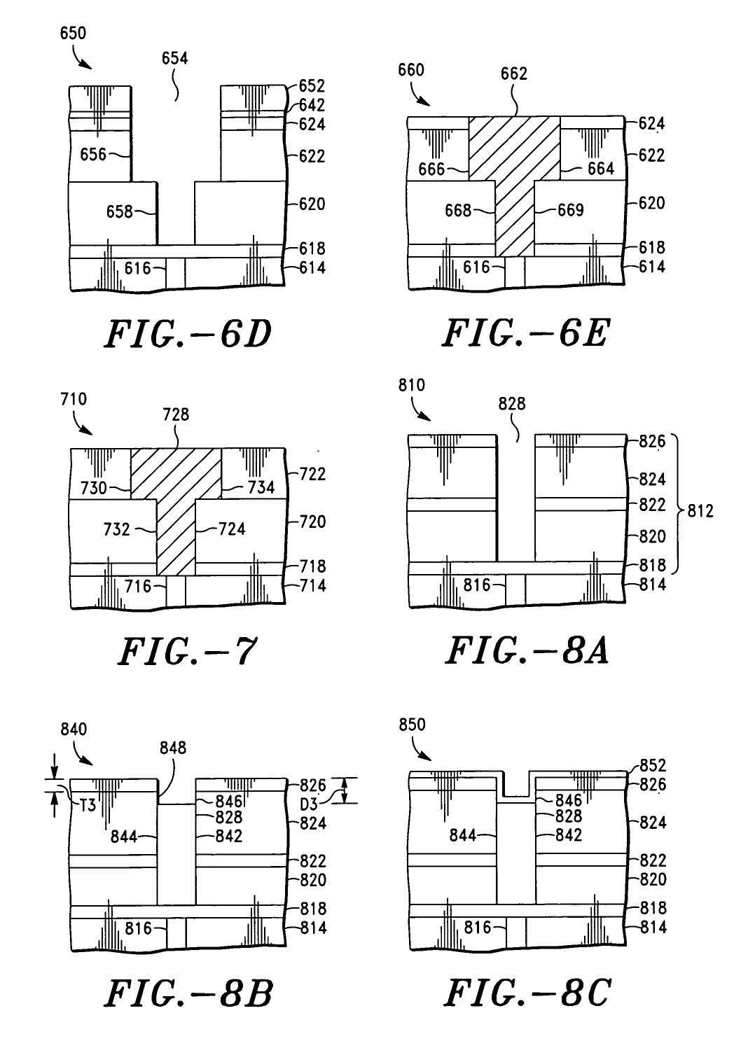

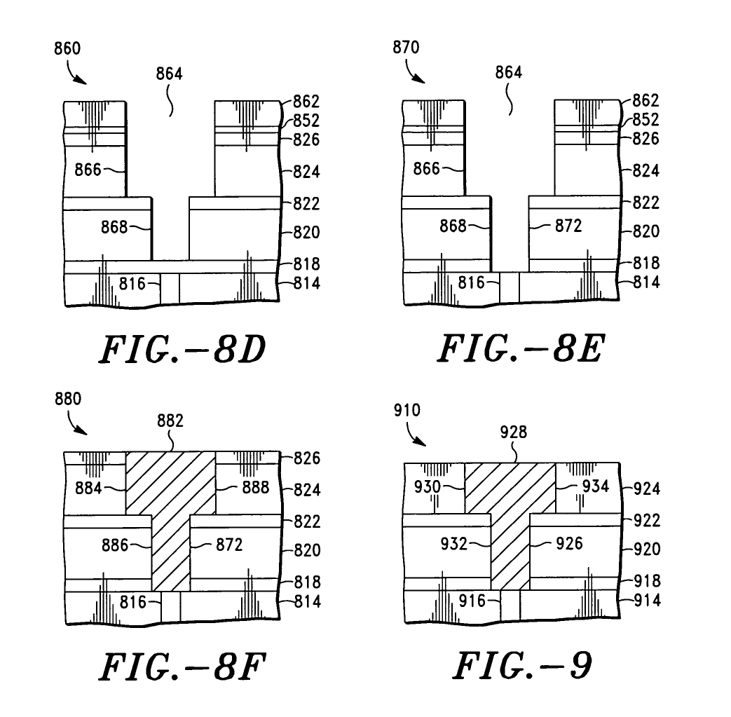

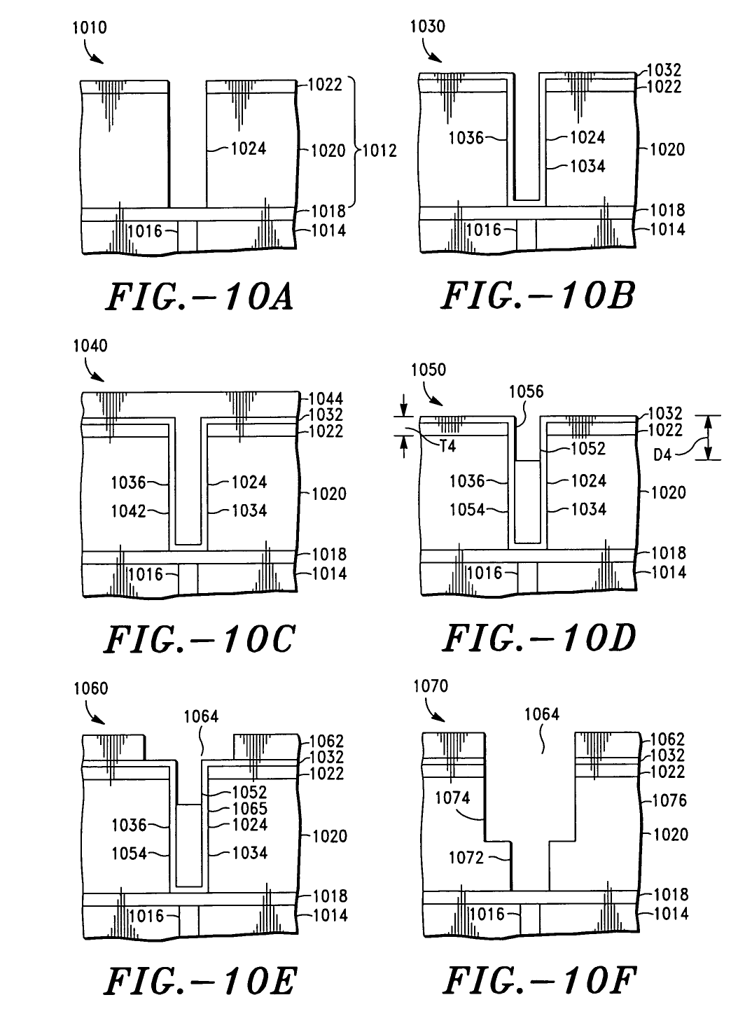

Techniques of the present invention as exemplified in FIGS. 3A-31, 4A, 4B and 5A-4C utilize one homogeneous dielectric layer for fabricating one or more dual damascene vias and interconnect lines. This technique requires a timed etch for fabricating the trench in the dielectric layer. However, it is well known that a timed etch can result in IC fabricating difficulties relating to difficulties in determining the end point of trench etching and/or obtaining a substantially flat etch front when etching the trench to the desired depth. In order to alleviate the difficulties resulting from a timed etch, it is also contemplated to obtain a trench etching end point by forming a trench and a via hole in dielectric layers having dissimilar etching characteristics as described in connection with FIGS. 6A-6E and 7, or by employing a trench etch stop layer as described in connection with FIGS. 8A-8F and 9.

In another embodiment of the present invention, FIG. 6A shows an IC structure 610 including a dielectric stack 612 that is deposited on a substrate, such as a semiconductor substrate 614. Electrically conductive element 616, positioned in substrate 614, provides an electrically conductive contact with one or more IC elements (not shown) of the substrate. Typical examples of electrically conductive elements include interconnects, vias and transistor gate contacts. Dielectric stack 612 is fabricated by means of a sequential deposition of a conventional via etch stop layer 618, a conventional first dielectric layer 620, a conventional second dielectric layer 622 and a third dielectric layer 624 preferably comprising a conventional ARC layer or a conventional hard mask layer or a conventional dual hard mask layer. First and second dielectric layers 620 and 622 respectively comprise dielectric materials having dissimilar etching characteristics. The expression “dissimilar etching characteristics” of two materials as defined herein, means etching properties of these materials such that one of the materials has a higher etch rate than the other material in a specific etch chemistry. Employing conventional anisotropic etching methods and materials, a via hole 626 is etched through layers 624, 622 and 620, see FIG. 6A. The via hole etch process is stopped on etch stop layer 618.

As depicted in FIG. 6B showing IC structure 630, via hole 626 is filled with a sacrificial via fill material 632, similar to sacrificial via fill 332 of IC structure 330 shown in FIG. 3B. Returning to FIG. 6B and employing techniques such as described in connection with FIGS. 3B and 3C, a conventional etch technique is employed to remove any overburden of the sacrificial layer from layer 624, and to remove a top portion of the sacrificial via fill, thereby reducing the height of the via fill to form a sacrificial via fill 634 and creating an unfilled via hole top portion or recess 636 having a side wall 638, similar to via fill 344, via hole top portion 346 and side wall 348 depicted in FIG. 3C. Typically, depth D2 of recess 636 exceeds thickness T2 of layer 624.

Novel IC structure 640 depicted in FIG. 6C, is fabricated according to techniques of the present invention by depositing a substantially conformal sacrificial liner 642 on layer 624 and on via fill 634, such that side wall 638 is coated with the sacrificial liner. Then, as illustrated in FIG. 6D, IC structure 650 is formed by depositing a conventional photoresist layer 652 on sacrificial liner 642. Subsequently, resist layer 652 is patterned and developed to form trench etch mask 654, see FIG. 6D. Employing conventional etch techniques, the trench etch pattern is anisotropically etched through layers 642 and 624, followed by a conventional anisotropic etch procedure of second dielectric layer 622, employing etch chemistries that are selective to first dielectric layer 620. In this procedure, first dielectric layer 620 is the etch stop for etching the trench pattern through second dielectric layer 622, as shown in FIG. 6D. The trench etch process can be utilized to simultaneously remove sacrificial fill 634 from the via hole. Alternatively, any remaining sacrificial fill 634 can be removed from the via hole in a separate process after etching the trench. Trench 656 is formed in layers 642, 624 and 622. Via hole 658 (FIG. 6D) positioned in first dielectric layer 620 comprises a lower portion of via 626 shown in FIG. 6A.

By analogy with the novel techniques described and illustrated in connection with FIGS. 3G-3I, resist layer 652 (FIG. 6D) and sacrificial liner 642 are removed from structure 650 shown in FIG. 6D. In a separate conventional anisotropic etching step, the via hole is ansisotrpically etched through etch stop layer 618. Thereafter, an IC structure 660, depicted in FIG. 6E, is fabricated by forming a dual damascene structure 662. This dual damascene structure includes an interconnect line 664 formed in trench 666 extending through layers 622 and 624. Dual damascene structure 662 also includes a via 668 that is formed in via hole 669 extending through layers 618 and 620. Via 668 contacts conductive element 616.

By analogy with the inventive techniques illustrated and described in connection with FIGS. 4A and 4B, it is also contemplated to remove sacrificial liner 642 from trench 656 shown in FIG. 6D through the techniques illustrated and described in connection with FIGS. 4A and 4B, i.e. removing sacrificial liner 642 by means of a conventional CMP technique for defining the interconnect line of the dual damascene structure. The resulting structure is similar to IC structure 660, shown in FIG. 6E.

Furthermore, by analogy with the inventive techniques that are illustrated and described in connection with FIGS. 5A-5C, layers 652, 642 and 624, shown in FIG. 6D, can be removed by employing techniques such as utilized for removing layers 526, 524 and 522 of structure 510 illustrated in FIG. 5A. A subsequent conventional dual damascene fabricating technique results in IC structure 710, depicted in FIG. 7, wherein features 714, 716, 718, 720, 722 and 724 are similar to features 614, 616, 618, 620, 622 and 658 respectively depicted in FIG. 6E. IC structure 710, shown in FIG. 7, includes a dual damascene structure 728 including an interconnect line 730 and a via 732. Interconnect line 730 is fabricated in trench 734 formed in second dielectric layer 722, while via 732 is fabricated in via hole 724 extending through first dielectric 720 and etch stop layer 718. Via 732 contacts conductive element 716.

In a further embodiment of the present invention, FIG. 8A depicts an IC structure 810 including a dielectric stack 812 that is deposited on a substrate such as a semiconductor substrate 814. Electrically conductive element 816, positioned in substrate 814, provides an electrically conductive contact with one or more IC elements (not shown) of the substrate. Dielectric stack 812 is fabricated by means of a sequential deposition of a conventional via etch stop layer 818, a conventional first dielectric layer 820, a conventional trench etch stop layer 822, a conventional second dielectric layer 824 and a third dielectric layer 826 preferably comprising a conventional ARC layer or a conventional hard mask layer or a conventional dual hard mask layer. First and second dielectric layers 820 and 824 respectively can comprise the same dielectric material, or layer 820 can comprise a dielectric material that is different from the dielectric material of layer 824. Employing conventional anisotropic etching methods and materials, a via hole 828 is etched through layers 826, 824, 822 and 820. The via hole etch process is stopped on etch stop layer 818.

As depicted in FIG. 8B, showing IC structure 840, via hole 828 is filled with a sacrificial via fill material 842, similar to sacrificial via fill 332 of IC structure 330 shown in FIG. 3B. Returning to FIG. 8B, a conventional etch technique such as etch back can be employed to remove any overburden of sacrificial fill material from third dielectric layer 826, and to remove a top portion of the sacrificial via fill, thereby reducing the height of the via fill to form a sacrificial fill 844 and creating an unfilled via hole top portion or recess 846 having a side wall 848, similar to via fill 344, unfilled via hole top portion 346 and side wall 348 depicted in FIG. 3C. Typically, depth D3 of recess 846 exceeds thickness T3 of layer 826.

Novel IC structure 850 depicted in FIG. 8C, is fabricated according to techniques of the present invention by depositing a substantially conformal sacrificial liner 852 on layer 826 and on via fill 844, such that side wall 846 is coated with the sacrificial liner. Then, as illustrated in FIG. 8D, IC structure 860 is formed by depositing a conventional photoresist 862 on sacrificial liner 852. Subsequently, resist layer 862 is patterned and developed to form trench etch mask 864. Employing conventional etch techniques, the trench etch pattern is anisotropically etched through layers 852 and 826, followed by a conventional anisotropic etch procedure of second dielectric layer 824 and stopping the trench etching procedure on trench etch stop layer 822. The trench etching procedure creates a trench 866 extending through layers 852, 826 and 824. This procedure shortens via hole 828 (FIG. 8A) to via hole 868 extending through layers 822 and 820, as shown in FIG. 8D. The trench etch process can be used to simultaneously remove sacrificial fill 844 (FIG. 8C) from via hole 868 (FIG. 8D). Alternatively, the sacrificial fill can be removed from via hole 868 in a separate procedure following trench etching. In a subsequent conventional anisotropic etch procedure, via hole 868 is extended through via etch stop layer 818 thereby creating a via hole 872 extending through layers 818, 820 and 822, as shown in IC structure 870, depicted in FIG. 8E. By analogy with the techniques described and illustrated in connection with FIGS. 3G-3I, resist layer 862 (FIG. 8E) and sacrificial liner 852 are removed from structure 870. Thereafter, employing conventional dual damascene techniques, an IC structure 880, depicted in FIG. 8F is formed having a dual damascene structure 882. This dual damascene structure includes an interconnect line 884 and a via 886. Interconnect line 884 is formed in trench 888 extending through layers 826 and 824, while via 886 is formed in via hole 872. Via 886 contacts conductive element 816 of substrate 814.

By analogy with the inventive techniques illustrated and described in FIGS. 4A and 4B it is also contemplated to remove sacrificial liner 852 from trench 866 shown in FIG. 8E through the techniques illustrated and described in connection with FIGS. 4A and 4B, i.e. removing sacrificial liner 852 by means of a CMP technique for defining the interconnect line of the dual damascene fabrication. The resulting structure is similar to IC structure 880, shown in FIG. 8F.

Furthermore, by analogy with the inventive techniques illustrated and described in connection with FIGS. 5A-5C, layers 862, 852 and 826, shown in FIG. 8E, can be removed by employing techniques such as utilized for removal of layers 526, 524 and 522 of structure 510 illustrated in FIG. 5A. A subsequent conventional dual damascene fabricating technique results in IC structure 910, depicted in FIG. 9 wherein features 914, 916, 918, 920, 922, 924 and 926 are similar to features 814, 816, 818, 820, 822, 824 and 872 respectively illustrated in FIG. 8F. IC structure 910, shown in FIG. 9, includes a dual damascene structure 928 including an interconnect line 930 and a via 932. Interconnect line 930 is fabricated in trench 934 formed in second dielectric layer 924, while via 932 is fabricated in via hole 926. Via 932 contacts conductive element 916.

Still another embodiment of the present invention is illustrated and described in connection with FIG. 10A-10I. FIG. 10A shows an IC structure 1010 that is similar to IC structure 310 shown in FIG. 3A. elements 1012, 1014, 1016, 1018, 1020 1022 and 1024 of IC structure 1010 shown in FIG. 10A are similar to elements 312, 314,. 316, 318, 320, 322 and 324 respectively of IC structure 310 depicted in FIG. 3A.

As depicted in FIG. 10B showing IC structure 1030, a sacrificial liner 1032 is deposited on layer 1022 and inside via hole 1024, covering substantially the entire surface 1034 of via hole 1024, thereby forming a lined via hole 1036. Then, as illustrated in FIG. 10C, a novel IC structure 1040 is fabricated by depositing a sacrificial via fill 1042 in lined via hole 1036. Typically, the sacrificial via fill results in an overburden 1044 of sacrificial via fill material on the portion of sacrificial liner 1032 that is deposited on layer 1022.

In a next processing step, a conventional etch back procedure is employed wherein any overburden 1044 (FIG. 10C) is removed from layer 1032. The etch back process is continued to remove an upper portion of via fill 1042 from lined via hole 1036, thereby forming IC structure 1050 shown in FIG. 10D. The etch back procedure results in forming an unfilled top portion, or recess, 1052 of lined via hole 1036. This also results in reducing the height of the via fill to form a sacrificial fill 1054. Unfilled top portion 1052 includes a sidewall 1056. The etch process for this etch back procedure is selective to sacrificial liner 1032. Typically, depth D4 of recess 1052 exceeds the combined thickness T4 of layers 1022 and 1033, see FIG. 10D. The novel fabricating process is continued, as shown in FIG. 10E illustrating IC structure 1060, by depositing a conventional photoresist layer 1062 on sacrificial liner 1032 as well as on sacrificial via fill 1054 in top portion 1052. Resist layer 1062 is then patterned and developed to form trench etch mask 1064.

Employing conventional anisotropic etching procedures and materials, the etch pattern of mask 1064 is etched through layers 1032 and 1022, see IC structure 1070 shown in FIG. 10F. The etch procedure is also utilized to remove sacrificial liner 1032 and via fill 1054 from upper section 1065 (FIG. 10E) of via 1024 wherein the trench will be fabricated, see FIG. 10F. Subsequently, a conventional anisotropic timed etch is employed to partly etch the trench etch pattern through dielectric layer 1020. The trench etch procedure can be utilized to simultaneously remove sacrificial fill 1054 (FIG. 10E) from lined via hole 1036 and to also remove sacrificial liner 1032 from the via hole. Alternatively the sacrificial fill and the sacrificial liner can be removed in a separate etching procedure after etching the trench. As shown in FIG. 10F, the trench etching procedure results in a via hole 1072 positioned in layer 1020, such that via hole 1072 comprises a lower portion of via hole 1024 (FIG. 10A). Also a trench 1074, see FIG. 10F, is formed in layers 1032 and 1022, and in upper portion 1076 of layer 1020 by means of this trench etching procedure. As shown in IC structure 1080 depicted in FIG. 10G, a conventional anisotropic etch technique is employed to extend via hole 1072 (FIG. 10F) through via etch stop layer 1018, thereby forming via hole 1082 as illustrated in FIG. 10G. Via hole 1082 exposes conductive element 1016.

In a next processing step, sacrificial layer 1036 is removed from layer 1022 using such techniques as are known for removal of the material that is used in layer 1022. These techniques can for example include etching, providing that dielectric layer 1020, substrate 1014 and conductive element 1016 are selective to the etching procedure. The resulting IC structure 1084, shown in FIG. 10H, depicts via hole 1082 as well as trench 1086 that is formed in layer 1022 and in upper portion 1088 of dielectric layer 1020. Finally, using dual damascene methods and materials such as are known to a person of ordinary skill in the art, conductive material is deposited simultaneously in via hole 1082 and in trench 1086. The simultaneous deposition of conductive material, for example a metal such as copper or aluminum, in via hole 1082 and trench 1086 results in IC structure 1090, illustrated in FIG. 10I, having a dual damascene structure 1092 that includes an interconnect line 1094 formed in trench 1086, and a via 1096 fabricated in via hole 1082. Interconnect line 1094 can be defined using well known techniques such as CMP and etch back. Via 1096 contacts conductive element 1016.

A novel alternative damascene fabrication technique can be employed for fabricating a dual damascene structure such as dual damascene structure 1092 shown in FIG. 10I. This alternative technique includes employing an IC structure such as IC structure 1080 depicted in FIG. 10G and subsequent employing the novel techniques such as described and illustrated in connection with FIGS. 4A and 4B.

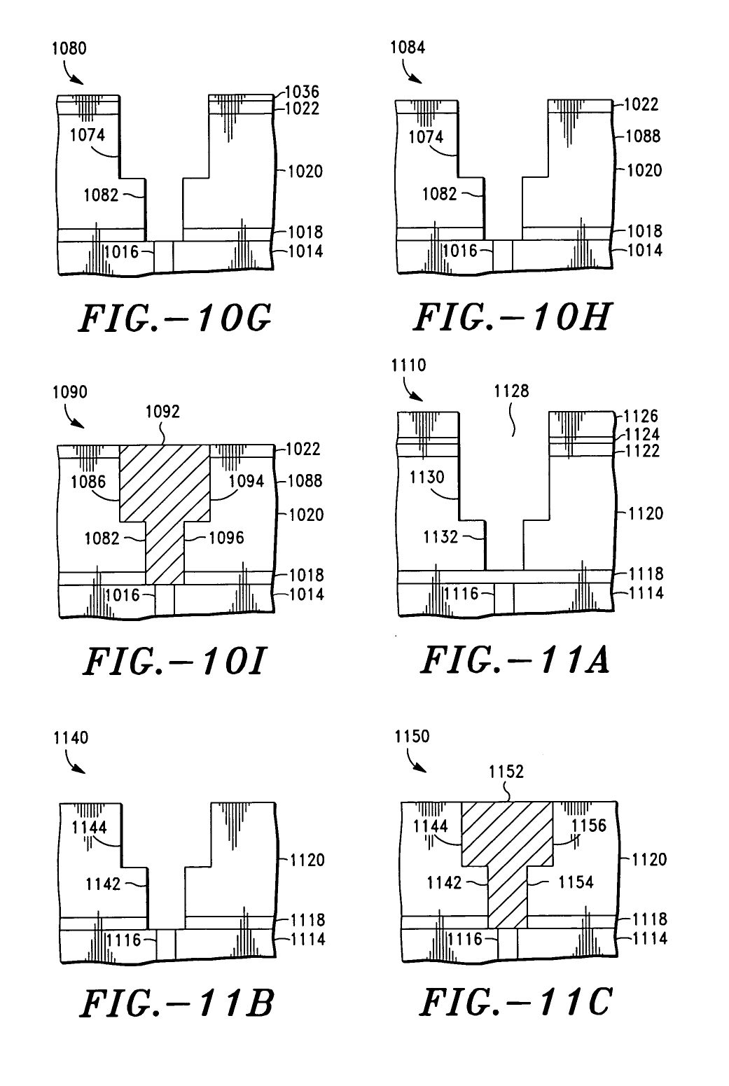

FIGS. 11A and 11B illustrate an additional dual damascene fabrication method of the present invention. FIG. 11A illustrates an IC structure 1110 that is similar to IC structure 1070 depicted in FIG. 10F. It is noted that features 1114, 1116, 1118, 1120, 1122, 1124, 1126, 1128, 1130 and 1132 shown in FIG. 11A, are similar to features 1014, 1016, 1018, 1020, 1022, 1032, 1062, 1064, 1074 and 1072 respectively depicted in FIG. 10F.

Returning to FIG. 11A, layers 1122, 1124 and 1126 are removed using such techniques as are known to a person of ordinary skill in the art for the removal of materials comprising these layers. Additionally, via hole 1132 is extended by etching the via pattern anisotropically through via etch stop layer 1118. Removal of layers 1122, 1124 and 1126, and etching the via pattern through via etch stop layer 1118 results in IC structure 1140, see FIG. 11B, showing an extended via hole 1142 and an interconnect line trench 1144. Thereafter, a conventional dual damascene technique is employed for simultaneously filling via hole 1142 and trench 1144 with a conductive material, for example a metal such as copper or aluminum, to fabricate IC structure 1150, shown in FIG. 11C. As a result a dual damascene structure 1152 is formed. This dual damascene structure includes via 1154 formed in a via hole 1142 and an interconnect line 1156 fabricated in trench 1144.

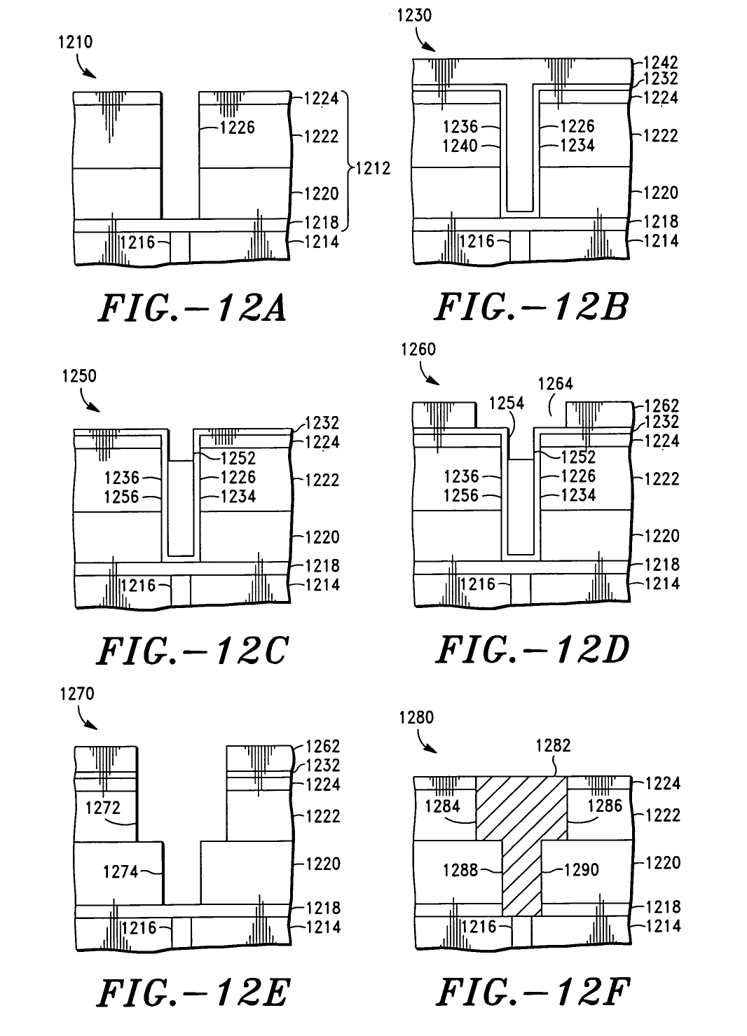

In another embodiment of the present invention, FIG. 12A shows an IC structure 1210 including a dielectric stack 1212 that is deposited on a substrate, such as a semiconductor substrate 1214. Electrically conductive element 1216, positioned in substrate 1214, provides an electrically conductive contact with one or more IC elements of the substrate. Dielectric stack 1212 is fabricated by means of a sequential deposition of a conventional via etch stop layer 1218, a conventional first dielectric layer 1220, a conventional second dielectric layer 1222 and a third dielectric layer 1224 preferably comprising a conventional ARC layer or a conventional hard mask layer or a conventional dual mask layer. First and second dielectric layers 1220 and 1222 respectively comprise dielectric materials having dissimilar etching characteristics. Employing conventional anisotropic etching methods and materials, a via hole 1226 is etched through layers 1224, 1222 and 1220, see FIG. 12A. The via hole etch process is stopped on etch stop layer 1218.

As illustrated in FIG. 12B depicting novel IC structure 1230, a sacrificial liner 1232 is deposited on layer 1224 and inside via hole 1226, covering substantially the entire surface 1234 of via hole 1226, thereby forming a lined via hole 1236. Then, a sacrificial via fill 1240 is deposited in lined via hole 1236. Typically, the sacrificial fill results in an overburden 1242 of sacrificial via fill material on the portion of sacrificial liner 1232 that is deposited on layer 1224.

Then, following etch back procedures similar to those illustrated and described in connection with FIG. 10D, overburden 1242 is removed. Also, an upper portion of via fill 1240 is removed from lined via hole 1236 thereby forming novel IC structure 1250 shown in FIG. 12C. IC structure 1250 includes an unfilled top portion, or recess, 1252 of lined via hole 1236. Recess 1252 is similar to recess 1052 of IC structure 1050 shown in FIG. 10D. Returning to FIG. 12C, top portion 1252 of lined via hole 1236 includes a sidewall 1254. It is noted that the etch back procedure of via fill 1240 is selective to sacrificial liner 1232. The etch back procedure results in reducing the height of the via fill to form a sacrificial via fill 1256. The novel fabricating process is continued, as shown in FIG. 12D illustrating IC structure 1260, by depositing a conventional photoresist 1262 on sacrificial liner 1232 as well as on sacrificial via fill 1256 in top portion 1252. Resist layer 1262 is then patterned and developed to form trench etch mask 1264.

The fabricating procedure is continued as shown in IC structure 1270 illustrated in FIG. 12E. Employing conventional anisotropic etch techniques, the etch pattern of trench mask 1264 is anisotropically etched through layers 1232 and 1224, followed by a conventional anisotropic etch procedure of second dielectric layer 1222, employing etch chemistries that are selective to first dielectric layer 1220 and to via etch stop layer 1218. In this procedure, first dielectric layer 1220 is the etch stop for etching the trench pattern through second dielectric layer 1222. The trench etching procedure results in forming a trench 1272 (FIG. 12E) in layers 1232, 1224 and 1222, and in forming a via hole 1274 in layer 1220. The trench etching process can be utilized to simultaneously remove sacrificial liner 1232 and sacrificial via fill 1256 from via hole 1274. Alternatively, sacrificial liner 1232 and sacrificial via fill 1256 can be removed from via hole 1274 in a separate etching process after fabricating trench 1272.

Employing techniques of the present invention as described and illustrated in connection with FIGS. 3G-3I, resist layer 1262 and sacrificial liner 1232 are removed from structure 1270 shown in FIG. 12F. In a separate conventional anisotropic etching step, the via hole is etched through etch stop layer 1218. Thereafter, an IC structure 1280 depicted in FIG. 12F, is fabricated by forming a dual damascene structure 1282. This dual damascene structure includes an interconnect line 1284 formed in trench 1286 extending through layers 1224 and 1222. The dual damascene structure also includes via 1288 in via hole 1290 extending through layers 1220 and 1218, such that via 1288 contacts conductive element 1216.

Utilizing techniques of the present invention as illustrated and described in connection with FIGS. 4A and 4B, it is also contemplated to remove sacrificial liner 1232 from third dielectric layer 1224 shown in FIG. 12E through the techniques described and illustrated in connection with FIGS. 4A and 4B, i.e. removing sacrificial liner 1232 by means of a conventional CMP technique for defining the interconnect line of the dual damascene structure. The resulting structure is similar to IC structure 1280, shown in FIG. 12F.

Furthermore, employing the inventive techniques that are illustrated and described in connection with FIGS. 11A-11C, layers 1262, 1232 and 1224 (FIG. 12E) can be removed by utilizing techniques such as are utilized for removing layers 1126, 1124 and 1122 respectively of IC structure 1110 illustrated in FIG. 11A. A subsequent conventional dual damascene fabricating technique results in IC structure 1310, depicted in FIG. 13, wherein features 1314, 1316, 1318, 1320, 1322 and 1324 are similar to features 1214, 1216, 1218, 1220, 1222 and 1290 respectively depicted in FIG. 12F. IC structure 1310 shown in FIG. 13, includes a dual damascene structure 1326 including an interconnect line 1328 and a via 1330. Interconnect line 1328 is fabricated in trench 1332 formed in second dielectric layer 1322, while via 1330 is fabricated in via hole 1324 extending through first dielectric layer 1320 and via etch stop layer 1318. Via 1330 contacts conductive element 1316.

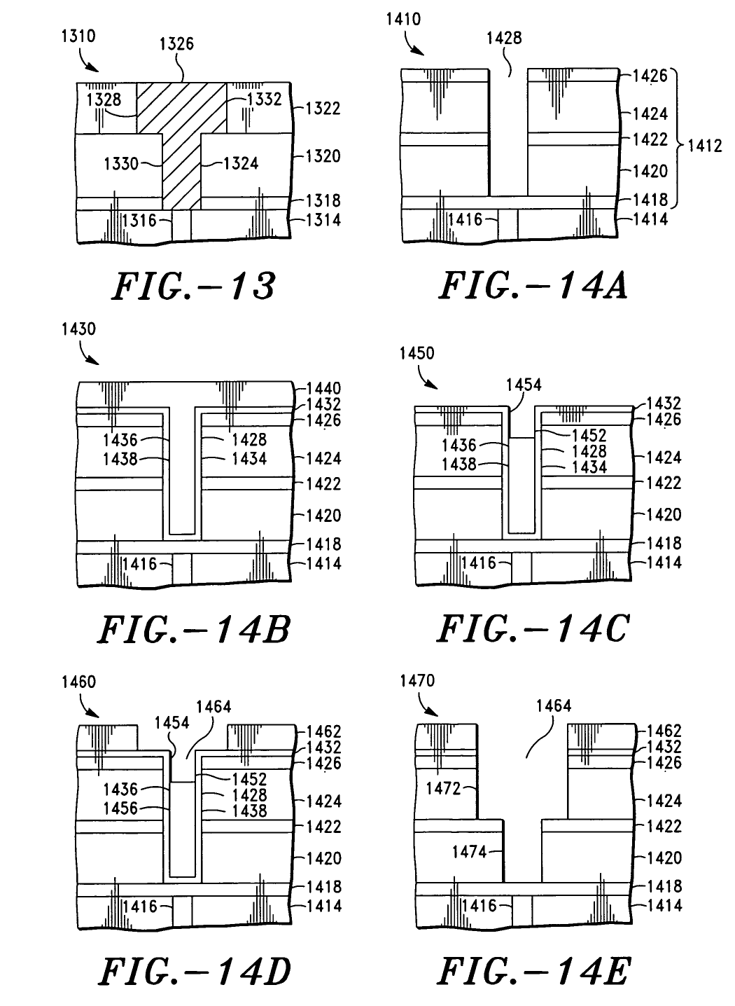

In still another embodiment of the present invention, FIG. 14A shows an IC structure 1410. Features 1412, 1414, 1416, 1418, 1420, 1422, 1424, 1426 and 1428 shown in FIG. 14A are similar to features 812, 814, 816, 818, 820, 822, 824, 826 and 828 respectively, depicted in FIG. 8A. As shown in IC structure 1430 illustrated in FIG. 14B, a sacrificial liner 1432 is deposited in via hole 1428 covering substantially the entire surface 1434 of via hole 1428, thereby forming lined via hole 1436. Additionally, sacrificial liner 1432 is deposited on layer 1426. Then, a sacrificial via fill 1438 is deposited in lined via hole 1436. Typically, the sacrificial fill results in an overburden 1440 of sacrificial via fill material on the portion of sacrificial liner 1432 that is deposited on layer 1426. Then, following etch back procedures similar to those illustrated and described in connection with FIG. 10D, overburden 1432 is removed. Also, an upper portion of via fill 1438 is removed from lined via hole 1436 thereby forming a novel IC structure 1450 shown in FIG. 14C. It is noted that the etch back procedure for removal of overburden 1440 and removal of the upper portion of via fill 1438, employs etching procedures that are selective to sacrificial liner 1432.

With reference to FIG. 14C, the etch back procedure of via fill 1438 results in an unfilled top portion, or recess, 1452 of lined via hole 1436. Recess 1452 is similar to recess 1052 of IC structure 1050 shown in FIG. 10D. Returning to FIG. 14C, top portion 1452 includes a sidewall 1454. Also, the height of the via fill is reduced to form a sacrificial via fill 1456. The novel fabricating process is continued, as shown in FIG. 14D illustrating IC structure 1460, by depositing a conventional photoresist 1462 on sacrificial liner 1432 and on via fill 1456 in top portion 1452. Resist layer 1462 is then patterned and developed to form trench etch mask 1464.

The fabricating procedure is continued as shown in IC structure 1470 depicted in FIG. 14E. Employing conventional etch techniques, the etch pattern of trench etch mask 1464 is anisotropically etched through layers 1432, 1426 and 1424. The trench etching procedure is stopped on etch stop layer 1422. This procedure creates a trench 1472 (FIG. 14E) in layers 1432, 1426 and 1424, while also creating a via hole 1474 in layers 1422 and 1420. The trench etching process can be employed to simultaneously remove sacrificial liner 1432 and sacrificial via fill 1456 from via hole 1474. Alternatively, sacrificial liner 1432 and sacrificial via fill 1456 can be removed from via hole 1474 in a separate etching process after fabricating trench 1472.

Utilizing techniques of the present invention as described and illustrated in connection with FIGS. 3G-3I, resist layer 1462 and sacrificial liner 1432 are removed from structure 1470 shown in FIG. 12E. In a separate conventional anisotropic etching step, the via hole is etched through etch stop layer 1418. Thereafter, an IC structure 1480 depicted in FIG. 14F, is fabricated by forming a dual damascene structure 1482. This dual damascene structure includes an interconnect line 1484 formed in a trench 1486 extending through layers 1426 and 1424. Dual damascene structure 1482 also includes a via 1488 that is formed in a via hole 1490 extending through layers 1422, 1420 and 1418, such that via 1488 contacts conductive element 1416.

Employing techniques of the present invention as illustrated and described in connection with FIGS. 4A and 4B, sacrificial liner 1432 is removed by means of a conventional CMP technique for defining the interconnect line of the dual damascene structure. The resulting structure is similar to IC structure 1480 shown in FIG. 14F.

Furthermore, employing the inventive techniques that are illustrated and described in connection with FIGS. 11A-11C, layers 1462, 1432 and 1426 (FIG. 14E) can be removed by utilizing techniques such as are utilized for removing layers 1126, 1124 and 1122 of IC structure 1110 illustrated in FIG. 11A. A subsequent conventional dual damascene fabricating technique results in IC structure 1510 depicted in FIG. 15, wherein features 1514, 1516, 1518, 1520 1522, 1524 and 1526 are similar to features 1414, 1416, 1418, 1420 1422, 1424 and 1490 respectively depicted in FIG. 14F. IC structure 1510 includes a dual damascene structure 1528 including an interconnect line 1530 and a via 1532. Interconnect line 1530 is fabricated in a trench 1534 formed in second dielectric layer 1524, while via 1532 is fabricated in via hole 1526 extending through trench etch stop layer 1522, first dielectric layer 1520 and through via etch stop layer 1518. Via 1532 contacts conductive element 1516.

Examples of suitable materials for use in dielectric layers of the present invention such as layers 320 (FIG. 3A), 620 and 622 (FIG. 6A), 820 and 824 (FIG. 8A), 1020 (FIG. 10A), 1220 and 1222 (FIG. 12), 1420 and 1424 (FIG. 14A) include silicon oxide. The expression “silicon oxide” as defined herein, includes SiO₂, related non-stoichiometric materials SiO_{X}. Related silica glasses include USG (undoped silica glass), FSG (fluorinated silica glass), borophosphosilicate glass (BPSG) and C-doped silicon oxide. The expressions: “silicon oxide”, “related non-stoichiometric materials SiOₓ” and “related dielectric silica glasses”, as defined herein, exclude C-doped silicon oxide. These dielectric materials suitable for use in the above enumerated dielectric layers have a low dielectric constant. Additionally other low dielectric constant materials are suitable for use in these layers, for example amorphous fluorinated carbon based materials, spin-on dielectric polymers such as fluorinated and non-fluorinated poly(arylene) ethers (commercially known as FLARE 1.0 and 2.0, which are available from Allied Signal Company), poly(arylene) ethers (commercially known as PAE 2-3, available from Schumacher Company), divinyl siloxane benzocyclobutane (DVSOBCB) or similar products and aero-gel.

Examples of suitable materials for use in sacrificial liners of the present invention such as sacrificial liners 352 (FIG. 3D), 624 (FIG. 6C), 852 (FIG. 8C), 1032 (FIG. 10B), 1232 (FIG. 12C) and 1432 (FIG. 10) include but are not limited to: (1) metals such as TaN, Ta, Ti, TiN deposited by ALD (atomic layer deposition), CVD (chemical vapor deposition or PVD (physical vapor deposition), (2) dielectrics such as SiOₓ and SiₓN_{y}H_{z} deposited by ALD, (3) carbon deposited in CVD, PVD or etch chambers, (4) Si or silicon compounds deposited by ALD, (5) dielectrics such as undoped or doped oxides or nitrides and (6) dielectrics based on SiOCH.

Suitable ARC materials for dielectric layers such as second dielectric layers 322 (FIG. 3B) and 1022 (FIG. 10A), as well as third dielectric layers 624 (FIG. 6A), 826 (FIG. 8A) and 1426 (FIG. 14A) include but are not limited to organic ARC such as polyimide and inorganic ARC such as silicon oxynitrides and silicon oxycarbides.

Examples of suitable materials for use in sacrificial via fills of the present invention such as via fills 332 (FIG. 3B), 634 (FIG. 6B), 844 (FIG. 8B), 1042 (FIG. 10C), 1240 (FIG. 12B), and 1438 (FIG. 14) include, but are not limited to, ARC.

Suitable materials for use in etch stop layers such as layers 318 (FIG. 3A), 618 (FIG. 6A), 814 and 822 (FIG. 8A), 1018 (FIG. 10A), 1218 (FIG. 12A), 1418 and 1422 (FIG. 14A) include, but are not limited to, CVD SiN, SiONₓ, SiCN and SiOCN.

Exemplary dual damascene structures of the present invention include dual damascene structures 382 (FIG. 31), 442 (FIG. 4B), 552 (FIG. 5C), 662 (FIG. 6E), 728 (FIG. 7), 882 (FIG. 8F), 928 (FIG. 9), 1092 (FIG. 101), 1152 (FIG. 11C), 1282 (FIG. 12F), 1326 (FIG. 13), 1482 (FIG. 14F), 1528 (FIG. 15). These dual damascene structures are fabricated in dielectric stacks of the present invention, such that the dual damascene structures are deposited in direct contact with the dielectric materials of the respective dielectric stacks. However, it is also contemplated to fabricated Cu comprising dual damascene structures similar to those enumerated immediately above, in interconnect line trenches and via holes that are lined with a Cu diffusion barrier layer as illustrated in FIGS. 16A-16C.

An embodiment of the present invention is schematically illustrated in FIG. 16A, showing an IC structure 1610 that similar to IC structures 370 (FIG. 3H) and 1084 (FIG. 10). Features 1612, 1614, 1616, 1618, 1620, 1622, 1624, 1626 and 1628 of IC structure 1610 shown in FIG. 16A are similar to features 312, 314, 316, 318, 320, 322, 368, 372 and 374 respectively of IC structure 370 shown in FIG. 3H, and features 1012, 1014, 1016, 1018, 1020, 1022, 1082, 1086 and 1088 respectively of IC structure 1084 shown in FIG. 10H.

With reference to FIG. 16B showing an IC structure 1640, a substantially conformal electrically conductive conventional Cu diffusion barrier layer 1642 is deposited in via hole 1624 and in trench 1626, thereby forming a Cu diffusion barrier layer lined via hole 1644 and a Cu diffusion barrier layer lined trench 1646. Additionally, Cu diffusion barrier layer 1642 is deposited on layer 1622. In a next processing step, a conventional Cu comprising metal 1648 is simultaneously deposited in lined via hole 1644 and in lined trench 1646. Typically, the metal deposition step results in forming a Cu metal overburden 1650 on Cu diffusion barrier layer 1642 that is formed on layer 1622. Methods for depositing Cu comprising metal, such as Cu or Cu alloys, are well known to persons of ordinary skill in the art. Conventional CMP is then employed to remove Cu overburden 1650. Cu diffusion barrier layer 1642 is similarly removed from layer 1622 by means of conventional CMP. Additional CMP is then performed if necessary to define the Cu structure, resulting in IC structure 1660 illustrated in FIG. 16C.

IC structure 1660 shown in FIG. 16C includes a Cu metal comprising dual damascene structure 1662 including a via 1664 and an interconnect line 1666, wherein the dual damascene structure is provided with a Cu diffusion barrier layer except on top surface 1668 of interconnect line 1666.

Suitable materials for electrically conductive Cu diffusion barrier layers for embodiments of the present invention, such as Cu diffusion barrier layer 1642 of IC structure 1640 (FIG. 16B), include but are not limited to conductors for example refractory metals such as Ta, Ti, TiW and compounds of refractory metals such as TiN, TiC, TaN and TaC, as well as combinations of these materials such as TaN/Ta and Ti/TaN/Ta.

Photoresist layers for trench etch masks of embodiments of the present invention as illustrated and described in connection with IC structures 354 (FIG. 3E), 650 (FIG. 6D) and 860 (FIG. 8D) are deposited on a sacrificial liner, as shown in more detail in FIG. 17, depicting IC structure 1710. Features 1712, 1714, 1716, 1718, 1720, 1722 and 1724 shown in FIG. 17 are similar to features 320, 322, 324, 344, 346, 352 and 356 respectively depicted in FIG. 3E. It is noted that photoresist layer 1724 is not in direct contact with dielectric materials, such as dielectric layers 1712 and 1714, of IC structure 1710.

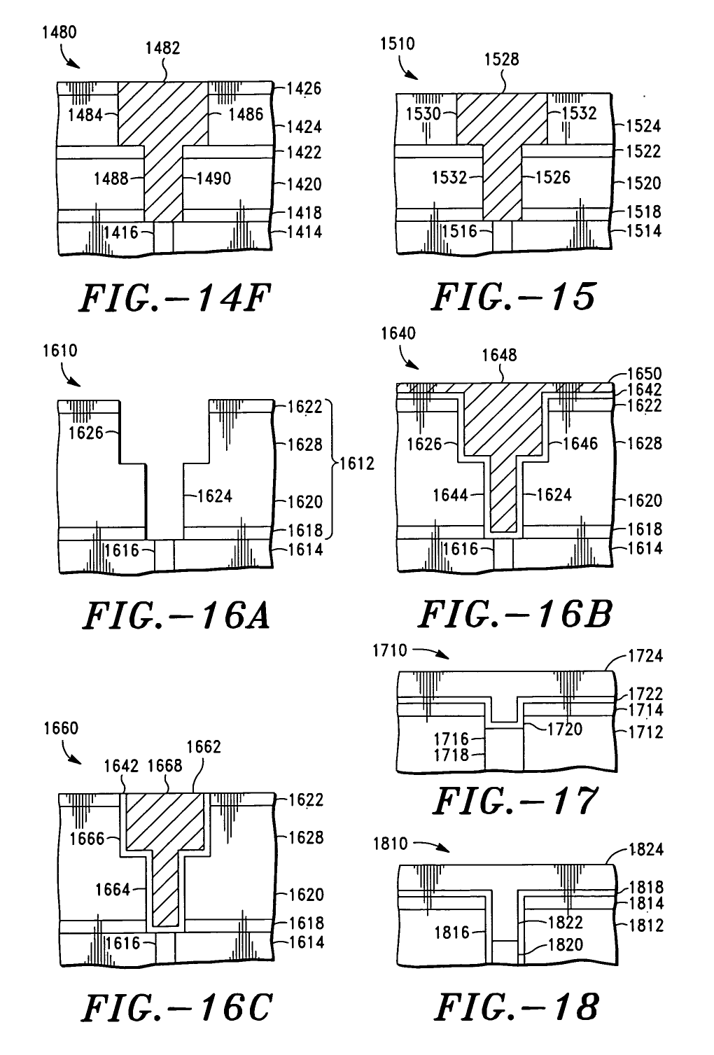

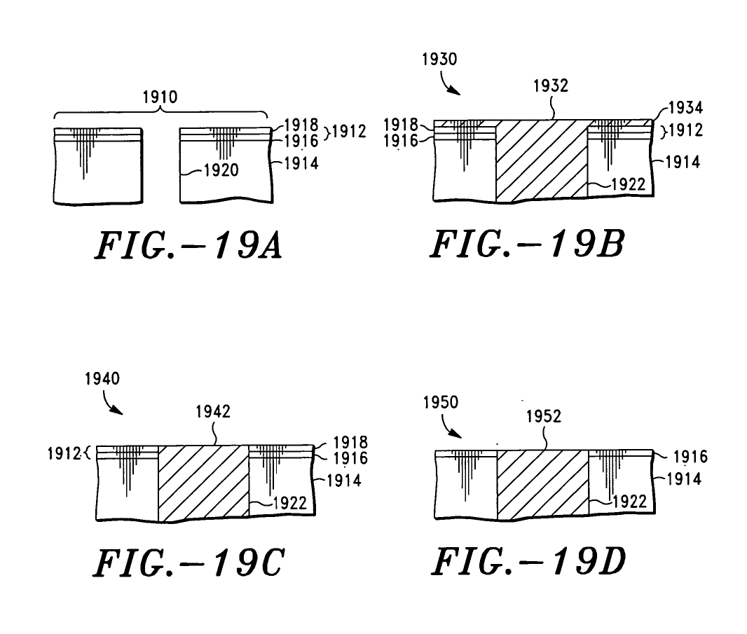

Photoresist layers for trench etch masks of embodiments of the present invention as illustrated and described in connection with IC structures 1060 (FIG. 10E), 1260 (FIG. 12D) and 1460 (FIG. 14D) are deposited partly on a sacrificial liner and partly on a sacrificial via fill. As illustrated in IC structure 1810, shown in FIG. 18, these photoresist layers are not in direct contact with dielectric materials such as any underlying dielectric layers. Features 1812, 1814, 1816, 1818, 1820, 1822 and 1824 shown in FIG. 18 are similar to features 1020, 1022, 1024, 1032, 1054, 1052 and 1062 respectively shown in FIG. 10E.

With reference to layers such as 322, 624, 826 and 1022, as described in connection with inventive IC structures 310, 610, 810 and 1010 it is contemplated to optionally utilize a dual hard mask, as illustrated in FIG. 19A. IC structure 1910 shown in FIG., 19A, includes a dual hard mask 1912 that is deposited on dielectric layer 1914, wherein dielectric layer 1914 is similar to, for example, dielectric layer 320 depicted in FIG. 3A. Returning to FIG. 19A, dual hard mask 1912 comprises a first hard mask layer 1916 including for example a dielectric material such as conventional TEOS SiO₂ and a second hard mask layer 1918 comprising either a dielectric material or a metal. The first and second hard mask layers are sequentially deposited on dielectric layer 1914. Subsequently, a via hole 1920 is fabricated in IC structure 1910, wherein via hole 1920 is similar to, for example, via hole 324 of IC structure 310, see FIG. 3A. Then, by analogy with, for example, FIG. 4A, a trench 1922 is fabricated in structure 1910 (FIG. 19A), as illustrated in IC structure 1930 shown in FIG. 19B. Furthermore, trench 1922 is filled with a conductive material 1932, see FIG. 19B, similar to conductive material 430 shown in FIG. 4A. Additionally, an overburden 1934 of conductive material 1932 may be formed on dual hard mask layer 1912, as depicted in FIG. 19B. Then, an IC structure 1940, depicted in FIG. 19C, is fabricated by removing overburden 1934 using for example conventional CMP (chemical mechanical polishing) resulting in interconnect line 1942. Where second hard mask layer 1918 includes a metal layer, it is necessary to remove this metal hard mask layer using conventional methods, resulting in IC structure 1950 including interconnect line 1952, see FIG. 19D. Also, where second hard mask layer 1918 comprises a metal, removal of metal overburden 1934 and metal layer 1918 (FIG. 19B) can be achieved by using the same CMP process, resulting in an IC structure similar to IC structure 1950 illustrated in FIG. 19D. If necessary, first hard mask layer 1916 can be removed using conventional techniques, such as CMP, to fabricate a structure similar to IC structure 550, shown in FIG. 5C.

Advantageously, embodiments of the present invention employ combinations of sacrificial liners and sacrificial via fills in order to fabricate a recess in a top portion of the via hole such that this recess is lined with sacrificial material. Additionally, these embodiments utilize a sacrificial liner that forms a barrier between the top layer of the dielectric stack and the photoresist trench mask layer. This novel combination of sacrificial liners and sacrificial via fills prevents, or at least substantially reduces, exposure of the photoresist trench mask layer to outgassing from the dielectric stack, particularly during the development of the trench etch mask. The present invention thus prevents, or at least substantially reduces, resist poisoning of the photoresist trench mask layer, particularly in the “via first” dual damascene fabricating techniques.

The invention has been described in terms of exemplary embodiments of the invention. One skilled in the art will recognize that it would be possible to construct the elements of the present invention from a variety of means and to modify the placement of components in a variety of ways. While the embodiments of the invention have been described in detail and shown in the accompanying drawings, it will be evident that various further modifications are possible without departing from the scope of the invention as set forth in the following claims.

We claim:

1. A method of fabricating a structure on a semiconductor substrate, the method comprising:
a) selecting the semiconductor substrate;
b) fabricating a dielectric stack on the substrate, wherein the dielectric stack includes (1) a top surface and (2) a bottom layer comprising a via etch stop layer that is deposited on the substrate;
c) employing a via etch pattern for anisotropically etching a first via hole in the dielectric stack such that etching the first via hole is stopped on the via etch stop layer;
d) depositing a first sacrificial via fill in the first via hole;
e) removing a top portion of the first sacrificial via fill, thereby forming (1) a second sacrificial via fill and (2) a via hole recess having a side wall; and
f) depositing a substantially conformal sacrificial liner (1) on the top surface of the stack and (2) in the via hole recess including the via hole recess side wall.

2. The structure fabricated according to the method of claim 1.

3. The method of claim 1 additionally comprising anisotropically etching an interconnect line trench (1) through the sacrificial liner that is deposited on the top surface of the stack and (2) partly through the dielectric stack, such that the trench is in substantial alignment with the first via hole, thereby forming a second via hole and wherein etching the trench additionally comprises removing the sacrificial liner and the second sacrificial via fill from the via hole.

4. The method of claim 3 additionally comprising anisotropically etching the via etch pattern through the via etch stop layer, thereby forming a third via hole.

5. The method of claim 4 additionally comprising simultaneously depositing an electrically conductive material in the trench and in the third via hole, thereby forming an electrically conductive dual damascene structure.

6. The method of claim 4 additionally comprising:
a) fabricating an electrically conductive Cu diffusion barrier layer inside the trench and inside the third via hole, thereby forming (1) a Cu diffusion barrier layer lined trench and (2) a Cu diffusion barrier layer lined third via hole; and
b) simultaneously depositing a Cu comprising metal in the Cu diffusion barrier layer lined trench and in the Cu diffusion barrier layer lined third via hole, thereby forming an electrically conductive dual damascene structure.

7. A method of fabricating a structure on a semiconductor substrate, the method comprising:
a) selecting the semiconductor substrate;
b) fabricating a dielectric stack on the substrate, wherein the dielectric stack includes (1) a top surface and (2) a bottom layer comprising a via etch stop layer that is deposited on the substrate;
c) employing a via etch pattern for anisotropically etching a first via hole in the stack such that etching the first via hole is stopped on the via etch stop layer;
d) depositing a substantially conformal sacrificial liner (1) on the top surface of the stack and (2) inside the first via hole, thereby forming a lined first via hole;
e) depositing a sacrificial via fill in the lined first via hole; and
f) removing an upper portion of the sacrificial via fill, thereby forming a lined recess in the lined first via hole.

8. The structure fabricated according to the method of claim 7.

9. The method of claim 7 additionally comprising anisotropically etching an interconnect line trench (1) through the sacrificial liner that is deposited on the top surface of the stack and (2) partly through the dielectric stack, such that the trench is in substantial alignment with the first via hole thereby forming a second via hole and wherein etching the trench additionally comprises removing the sacrificial liner and the sacrificial via fill from the via hole.

10. The method of claim 9 additionally comprising anisotropically etching the via etch pattern through the via etch stop layer, thereby forming a third via hole.

11. The method of claim 10 additionally comprising simultaneously depositing an electrically conductive material in the trench and in the third via hole, thereby forming an electrically conductive dual damascene structure.

12. The method of claim 10 additionally comprising:
a) fabricating an electrically conductive Cu diffusion barrier layer inside the trench and inside the third via hole, thereby forming (1) a Cu diffusion barrier layer lined trench and (2) a Cu diffusion barrier layer lined third via hole; and
b) simultaneously depositing a Cu comprising metal in the Cu diffusion barrier layer lined trench and in the Cu diffusion barrier layer lined third via hole, thereby forming an electrically conductive dual damascene structure.

13. A method of fabricating a structure on a semiconductor substrate, the method comprising:
a) selecting a semiconductor substrate;
b) depositing a via etch stop layer on the substrate;
c) depositing a first dielectric layer on the etch stop layer;
d) depositing a second dielectric layer, having a thickness T1, on the first dielectric layer;
e) anisotropically etching a first via hole through the second and first dielectric layers such that etching the first via hole is stopped on the via etch stop layer;
f) depositing a first sacrificial via fill in the first via hole and on the second dielectric layer;
g) removing the first sacrificial via fill from (1) the second dielectric layer and (2) a top portion of the first via hole, thereby forming (i) a second sacrificial via fill and (ii) a via hole recess having a side wall and having a depth D1; and
h) depositing a substantially conformal sacrificial liner on (1) the second dielectric layer and (2) in the via hole recess including the via hole recess side wall.

14. The method of claim 13 additionally comprising:
a) depositing a photoresist layer on the sacrificial liner;
b) developing an interconnect line trench etch pattern in the photoresist layer such that the etch pattern is substantially aligned with the first via hole;
c) employing a timed etch for anisotropically etching the trench etch pattern through (1) the sacrificial liner that is deposited (i) on the second dielectric layer and (ii) in the recess (2) the second sacrificial via fill and (3) partly through the second dielectric layer, thereby forming a second via hole;
d) extending the second via hole through the via etch stop layer, thereby forming a third via hole;
e) removing the photoresist layer; and
f) removing the sacrificial liner from the second dielectric layer thereby forming an interconnect line trench extending through the second dielectric layer and partly through the first dielectric layer, wherein the trench and the third via hole are adapted for fabricating a dual damascene structure.

15. The method of claim 14 wherein the second dielectric layer is selected from the group consisting of ARC, hard mask and dual hard mask.

16. The method of claim 14 wherein D1 exceeds T1.

17. The method of claim 14 wherein materials comprising the first sacrificial via fill are substantially the same as materials comprising the sacrificial liner.

18. The method of claim 14 wherein the materials comprising the first sacrificial fill are different from the materials comprising the sacrificial liner.

19. A method of fabricating a structure on a semiconductor substrate, the method comprising:
a) selecting the semiconductor substrate;
b) depositing a via etch stop layer on the substrate;
c) depositing a first dielectric layer on the via etch stop layer;
d) depositing a second dielectric layer on the first dielectric layer wherein the first and second dielectric layers have dissimilar etching characteristics;
e) depositing a third dielectric layer having a thickness T2, on the second dielectric layer;
f) anisotropically etching a first via hole through the third, second and first dielectric layers such that etching the first via hole is stopped on the etch stop layer;
g) depositing a first sacrificial via fill in the first via hole and on the third dielectric layer;
h) removing the first sacrificial via fill from (1) the third dielectric layer and (2) a top portion of the first via hole, thereby forming (i) a second sacrificial via fill and (ii) a via hole recess having a side wall and having a depth D2; and
i) depositing a substantially conformal sacrificial liner on (1) the third dielectric layer and (2) in the via hole recess including the via hole recess side wall.

20. The method of claim 19 additionally comprising:
a) depositing a photoresist layer on the sacrificial liner;
b) developing an interconnect line trench etch pattern in the photoresist layer such that the etch pattern is substantially aligned with the first via hole;
c) anisotropically etching the trench etch pattern through (1) the sacrificial liner that is deposited (i) on the third dielectric layer and (ii) in the recess, (2) the second sacrificial via fill, (3) the third dielectric layer and (4) the second dielectric layer and then stopping at the first dielectric layer, by using an etching technique that is selective to the first dielectric layer thereby forming a second via hole
d) extending the second via hole through the via etch stop layer, thereby forming a third via hole; and
e) removing the photoresist layer; and
f) removing the sacrificial layer from the third dielectric layer thereby forming an interconnect line trench extending through the second and third dielectric layers, wherein the trench and the third via hole are adapted for fabricating a dual damascene structure.

21. A method of fabricating a structure on a semiconductor substrate, the method comprising:
a) selecting the semiconductor substrate;
b) depositing a via etch stop layer on the substrate;
c) depositing a first dielectric layer on the via etch stop layer;
d) depositing a trench etch stop layer on the first dielectric layer;
e) depositing a second dielectric layer on the trench etch stop layer;
f) depositing a third dielectric layer, having a thickness T3, on the second dielectric layer;
g) anisotropically etching a first via hole through the (1) the third dielectric layer (2) the second dielectric layer (3) the etch stop layer and (4) the first dielectric layer, wherein etching the first via hole is stopped on the via etch stop layer;
h) depositing a first sacrificial via fill in the first via hole and on the third dielectric layer;
i) removing the first sacrificial via fill from (1) the third dielectric layer and (2) a top portion of the first via hole, thereby forming (i) a second sacrificial via fill and (ii) a via hole recess having a side wall and having a depth D3; and
j) depositing a substantially conformal sacrificial liner on (1) the third dielectric layer and (2) in the via hole recess including the via hole recess side wall.

22. The method of claim 21 additionally comprising:
a) depositing a photoresist layer on the sacrificial liner;
b) developing an interconnect line trench etch pattern in the photoresist layer such that the etch pattern is substantially aligned with the first via hole;
c) anisotropically etching the trench etch pattern through (1) the sacrificial liner that is deposited (i) on the third dielectric layer and (ii) in the recess, (2) the second sacrificial via fill, (3) the third dielectric layer and (4) the second dielectric layer and then stopping at the trench etch stop layer, thereby forming a second via hole;
d) extending the second via hole through the via etch stop layer, thereby forming a third via hole; and
e) removing the photoresist layer; and
f) removing the sacrificial layer from the third dielectric layer thereby forming an interconnect line trench extending through the second and third dielectric layers, wherein the trench and the third via hole are adapted for forming a dual damascene structure.

23. A method of fabricating a structure on a semiconductor substrate, the method comprising:
a) selecting the semiconductor substrate;
b) depositing a via etch stop layer on the substrate;
c) depositing a first dielectric layer on the via etch stop layer;
d) depositing a second dielectric layer, having a thickness T4, on the first dielectric layer;
e) anisotropically etching a first via hole through the second and first dielectric layers such that etching the first via hole is stopped on the via etch stop layer;
f) depositing a substantially conformal sacrificial liner inside the first via hole and on the second dielectric layer, thereby forming a lined via hole;
g) depositing a sacrificial fill on the sacrificial liner and in the lined via hole thereby forming (1) a first filled via hole and (2) a sacrificial fill overburden on the sacrificial liner that is deposited on the second dielectric layer; and
h) removing (1) the sacrificial fill overburden and (2) an upper portion of the sacrificial fill in the first filled lined hole, thereby forming (i) a second filled via hole and (ii) a lined recess in the lined first via hole wherein the lined recess includes a side wall and a depth D4.

24. The method of claim 23 additionally comprising:
a) depositing a photoresist layer (1) on the sacrificial liner that is deposited on the second dielectric layer and (2) in the lined recess including the side wall;
b) developing an interconnect line trench etch pattern in the photoresist layer such that the etch pattern is substantially aligned with the first via hole;
c) employing a timed etch for anisotropically etching the etch pattern through (1) the sacrificial liner that is deposited on (i) the second dielectric layer and (ii) in the recess (2) the sacrificial fill that is deposited in the second filled via hole, (3) the sacrificial liner that is deposited inside the second filled via hole, (4) the second dielectric layer and (5) partly through the first dielectric layer, thereby forming a second via hole;
d) extending the first via hole through the via etch stop layer, thereby forming a third via hole;
e) removing the photoresist layer from the sacrificial liner; and
f) removing the sacrificial liner from the second dielectric layer thereby forming an interconnect line trench extending through the second dielectric layer and partly through the first dielectric layer, wherein the trench and the third via hole are adapted for fabricating a dual damascene structure.

25. The method of claim 24 wherein the second dielectric layer is selected from the group consisting of ARC, hard mask and dual hard mask.

26. The method of claim 24 wherein D4 exceeds T4.
